(19) United States
(12) Patent Application Publication
(10) Pub. No.: US 2026/0324103 A1
(43) Pub. Date: Oct. 15, 2026

(54) PHOTODETECTION ELEMENT AND METHOD FOR MANUFACTURING PHOTODETECTION ELEMENT

(71) Applicant: HAMAMATSU PHOTONICS K.K., Hamamatsu-shi (JP)

(72) Inventors: Masanori OKADA, Shizuoka (JP); Yuta TSUJI, Shizuoka (JP); Ryutaro TSUCHIYA, Shizuoka (JP)

(73) Assignee: HAMAMATSU PHOTONICS K.K., Hamamatsu-shi (JP)

(21) Appl. No.: 19/463,645

(22) Filed: Jan. 29, 2026

(30) Foreign Application Priority Data
Feb. 3, 2025 (JP) 2025-016176
Feb. 3, 2025 (JP) 2025-016178
Jun. 17, 2025 (JP) 2025-101384

(51) Int. Cl. H10F 39/10; H10F 30/225; H10F 77/30; H10F 77/40

(52) U.S. Cl. CPC H10F 39/107; H10F 30/225; H10F 77/306; H10F 77/407

(57) ABSTRACT

A photodetection element includes a semiconductor substrate. The semiconductor substrate includes a first epitaxial semiconductor layer and a second epitaxial semiconductor layer. The first epitaxial semiconductor layer includes an epitaxial semiconductor region and a plurality of semiconductor regions each constituting an avalanche photodiode together with the epitaxial semiconductor region. The semiconductor substrate is provided with a trench surrounding the semiconductor region. The epitaxial semiconductor region has an impurity concentration higher than an impurity concentration of the second epitaxial semiconductor layer. The second epitaxial semiconductor layer has a thickness greater than a thickness of the first epitaxial semiconductor layer. A sum of the thickness of the first epitaxial semiconductor layer and the thickness of the second epitaxial semiconductor layer is 20 μm or more and 50 μm or less.

### TECHNICAL FIELD

The present disclosure relates to a photodetection element and a method for manufacturing a photodetection element.

### BACKGROUND

As a conventional photodetection element, for example, there is a photoelectric conversion device described in Japanese Unexamined Patent Publication No. 2022-73873. This photoelectric conversion device is a back-illuminated type photoelectric conversion device and includes a substrate having a single semiconductor element layer including an avalanche photodiode. The semiconductor element layer is composed of a first conductivity type semiconductor region and a second conductivity type semiconductor region. In a back-illuminated type photoelectric conversion device, the thickness of the semiconductor element layer tends to be smaller compared to a front-illuminated type photoelectric conversion device, and for example, the thickness is 11 μm or less.

### SUMMARY

As described above, the photoelectric conversion device described in Japanese Unexamined Patent Publication No. 2022-73873 is, for example, a back-illuminated type photoelectric conversion device, and in a back-illuminated type photoelectric conversion device, the thickness of the semiconductor element layer tends to be small. In a configuration in which the thickness of the semiconductor element layer tends to be small, it is difficult to increase the length of the optical path in the photoelectric conversion device, and it is difficult to improve the quantum efficiency, which indicates the probability that incident light generates carriers. The quantum efficiency affects the detection efficiency, which indicates the number of detected photons relative to the number of incident photons in a photodetection element. For example, when the quantum efficiency is improved, the detection efficiency in the photodetection element increases.

Furthermore, in a configuration in which the thickness of the semiconductor element layer tends to be small, secondary photons of carriers multiplied in a certain avalanche photodiode tends to enter an adjacent avalanche photodiode. That is, in a configuration in which the thickness of the semiconductor element layer tends to be small, there is also a problem that crosstalk is difficult to reduce.

From the above, a configuration in which the thickness of the semiconductor element layer tends to be small makes it difficult to improve the detection efficiency in a photodetection element and also makes it difficult to reduce crosstalk.

An object of the present disclosure is to provide a photodetection element that improves detection efficiency and controls crosstalk, and a method for manufacturing such a photodetection element.

### Means for Solving the Problems

A photodetection element according to one aspect of the present disclosure is [1] “a photodetection element including: a semiconductor substrate including a first surface to be a light-incident surface and a second surface located on a side opposite to the first surface; and a plurality of lenses provided on the first surface, wherein the semiconductor substrate includes a first epitaxial semiconductor layer including the second surface and a second epitaxial semiconductor layer located on a side opposite to the second surface with respect to the first epitaxial semiconductor layer, the first epitaxial semiconductor layer includes an epitaxial semiconductor region of a first conductivity type and a plurality of semiconductor regions of a second conductivity type, each of which includes the second surface and constitutes an avalanche photodiode together with the epitaxial semiconductor region, the second epitaxial semiconductor layer is adjacent to the epitaxial semiconductor region between the first surface and the epitaxial semiconductor region, each of the plurality of lenses is disposed on the first surface to overlap a corresponding semiconductor region among the plurality of semiconductor regions when viewed from a thickness direction of the semiconductor substrate, the semiconductor substrate is provided with a trench that surrounds the semiconductor region when viewed from the thickness direction and extends in the thickness direction, the epitaxial semiconductor region has an impurity concentration higher than an impurity concentration of the second epitaxial semiconductor layer, the second epitaxial semiconductor layer has a thickness greater than a thickness of the first epitaxial semiconductor layer, and a sum of the thickness of the first epitaxial semiconductor layer and the thickness of the second epitaxial semiconductor layer is 20 μm or more and 50 μm or less.”

### BRIEF DESCRIPTION OF THE DRAWINGS

FIG. 1 is a plan view schematically illustrating a photodetection element according to a first embodiment.

FIG. 2 is a partial cross-sectional view illustrating the photodetection element illustrated in FIG. 1.

FIG. 3 is an enlarged view of a part of the cross-sectional view illustrated in FIG. 2.

FIG. 4 is a partial plan view of the photodetection element illustrated in FIG. 1.

FIG. 5 is a diagram illustrating an example of a change in impurity concentration in the photodetection element illustrated in FIG. 1.

FIG. 6 is a diagram illustrating another example of a change in impurity concentration in the photodetection element illustrated in FIG. 1.

FIG. 7 is a diagram for explaining a method for manufacturing the photodetection element illustrated in FIG. 1.

FIG. 8 is a diagram for explaining the method for manufacturing the photodetection element illustrated in FIG. 1.

FIG. 9 is a diagram for explaining the method for manufacturing the photodetection element illustrated in FIG. 1.

FIG. 10 is a diagram for explaining the method for manufacturing the photodetection element illustrated in FIG. 1.

FIG. 11 is a diagram for explaining the method for manufacturing the photodetection element illustrated in FIG. 1.

FIG. 12 is a diagram for explaining the method for manufacturing the photodetection element illustrated in FIG. 1.

FIG. 13 is a plan view schematically illustrating a photodetection element according to a second embodiment.

FIG. 14 is a partial cross-sectional view illustrating the photodetection element illustrated in FIG. 13.

FIG. 15 is a diagram for explaining a method for manufacturing the photodetection element illustrated in FIG. 13.

FIG. 16 is a diagram for explaining the method for manufacturing the photodetection element illustrated in FIG. 13.

FIG. 17 is a diagram for explaining the method for manufacturing the photodetection element illustrated in FIG. 13.

FIG. 18 is a diagram for explaining the method for manufacturing the photodetection element illustrated in FIG. 13.

FIG. 19 is a diagram for explaining the method for manufacturing the photodetection element illustrated in FIG. 13.

FIG. 20 is a diagram for explaining the method for manufacturing the photodetection element illustrated in FIG. 13.

FIG. 21 is a diagram for explaining the method for manufacturing the photodetection element illustrated in FIG. 13.

FIG. 22 is a partial cross-sectional view illustrating a photodetection element according to a third embodiment.

FIG. 23 is a diagram for explaining a method for manufacturing the photodetection element illustrated in FIG. 22.

FIG. 24 is a diagram for explaining the method for manufacturing the photodetection element illustrated in FIG. 22.

FIG. 25 is a diagram for explaining the method for manufacturing the photodetection element illustrated in FIG. 22.

FIG. 26 is a diagram for explaining the method for manufacturing the photodetection element illustrated in FIG. 22.

FIG. 27 is a diagram for explaining the method for manufacturing the photodetection element illustrated in FIG. 22.

FIG. 28 is a diagram for explaining the method for manufacturing the photodetection element illustrated in FIG. 22.

### DETAILED DESCRIPTION

Hereinafter, embodiments will be described in detail with reference to the accompanying drawings. In the description, the same reference numerals are used for the same elements or elements having the same functions, and redundant description is omitted.

### First Embodiment

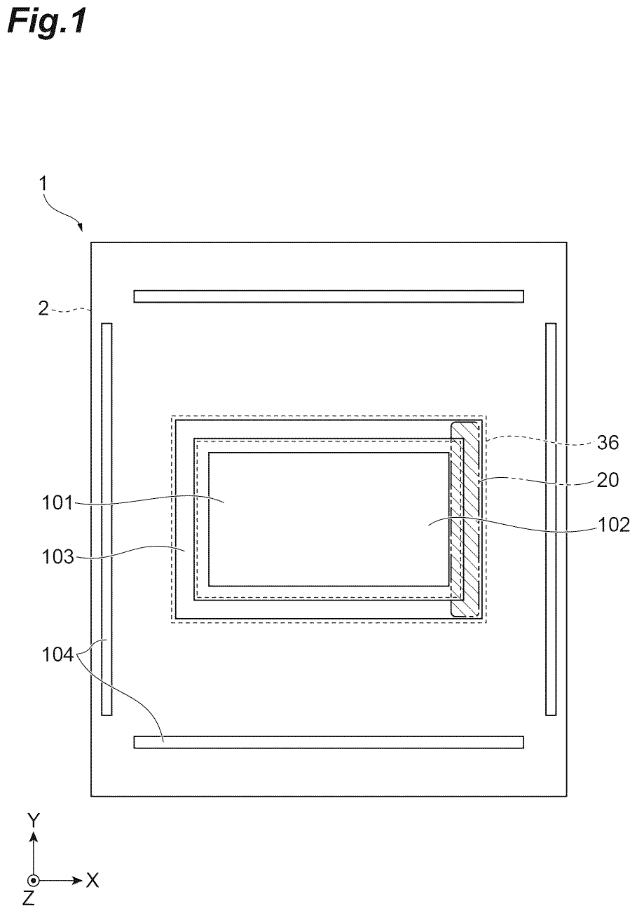

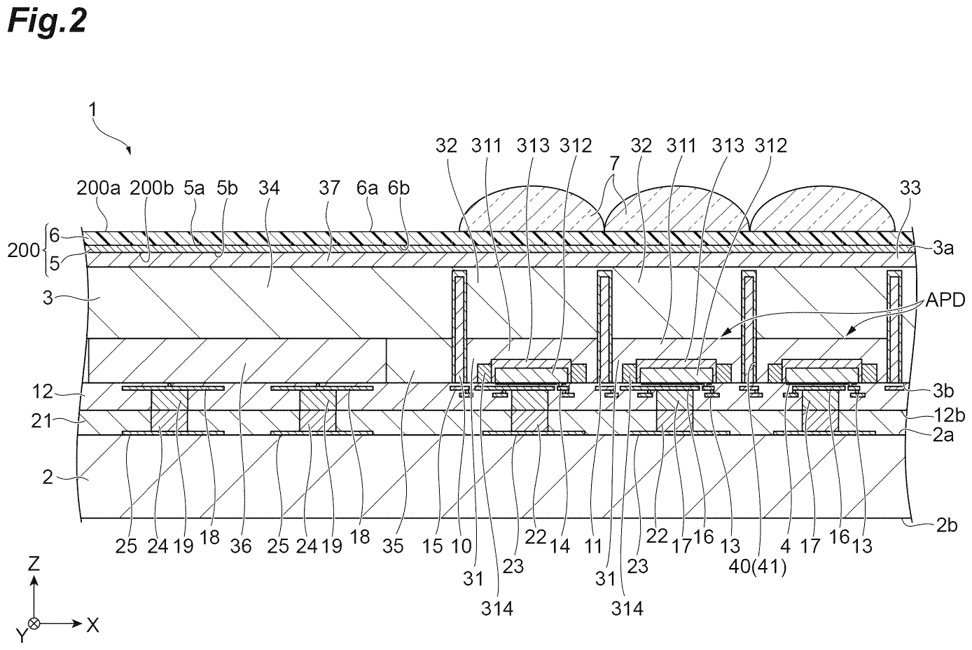

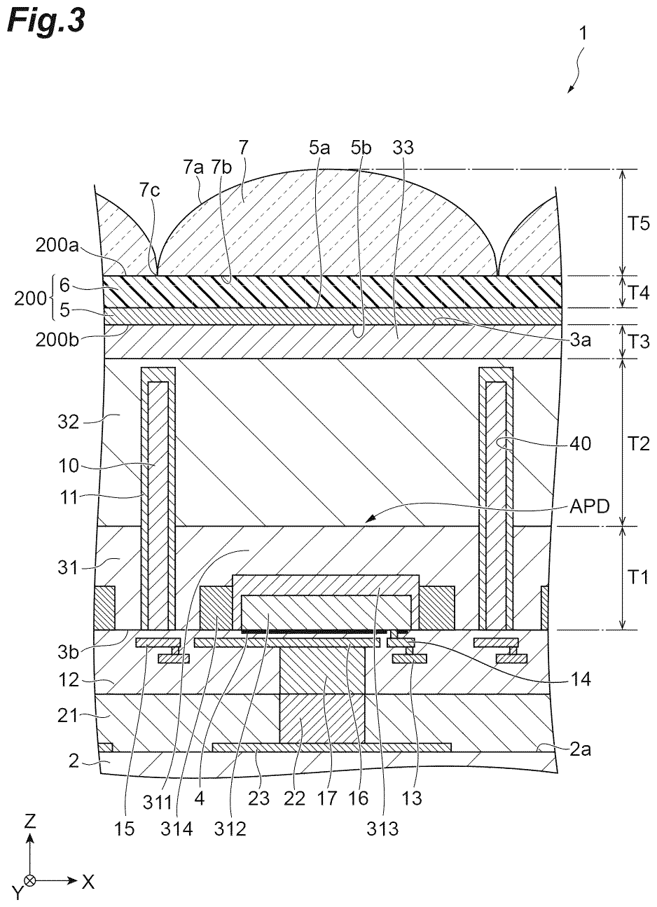

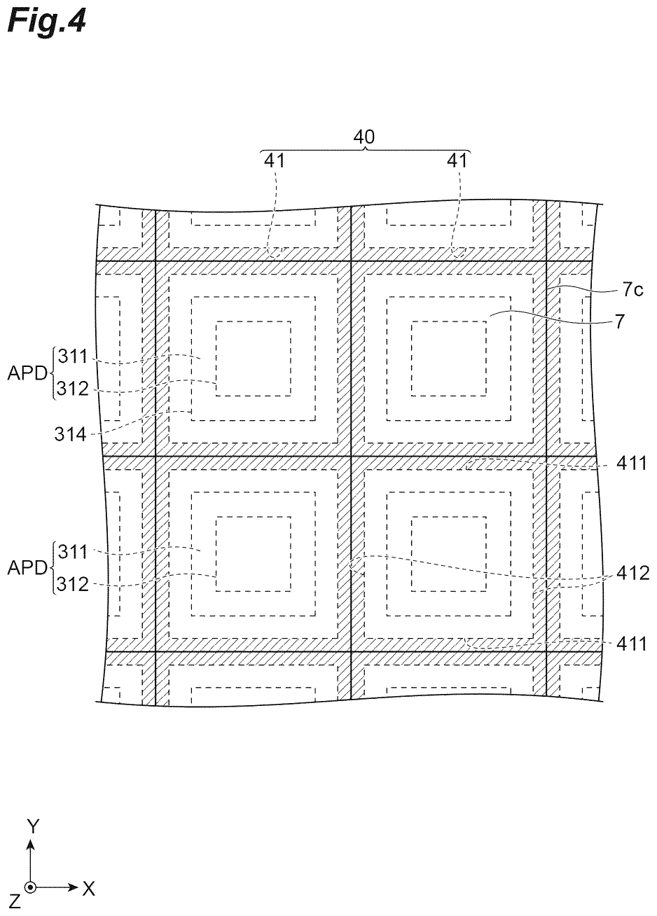

Configuration of Photodetection Element With reference to FIGS. 1 to 4, a configuration of a photodetection element according to a first embodiment will be described. FIG. 1 is a plan view schematically illustrating a photodetection element according to one embodiment. FIG. 2 is a partial cross-sectional view illustrating the photodetection element illustrated in FIG. 1. FIG. 3 is an enlarged view of a part of the cross-sectional view illustrated in FIG. 2. FIG. 4 is a partial plan view of the photodetection element illustrated in FIG. 1.

The photodetection element of the present embodiment is a back-illuminated type optical semiconductor element and detects incident light as a current signal. In the present embodiment, the photodetection element is configured as a SPAD (Single Photon Avalanche Diode) array. The photodetection element configured as a SPAD array includes a plurality of cell units each including an avalanche photodiode and a quenching element connected in series with each other. Each cell unit constitutes a channel that independently outputs a signal.

As illustrated in FIG. 1, a photodetection element 1 according to the present embodiment is formed in a substantially rectangular plate shape. In the following description, the thickness direction of the photodetection element 1 is referred to as a Z-axis direction, one direction perpendicular to the Z-axis direction is referred to as an X-axis direction, and a direction perpendicular to the Z-axis direction and the X-axis direction is referred to as a Y-axis direction. The photodetection element 1 includes a light-receiving area 101, a cathode area 102, an anode area 103, and a wire pad area 104.

The light-receiving area 101 is a region that generates charge carriers by incidence of light. In the light-receiving area 101, a plurality of cell units (pixels) each including an avalanche photodiode, which will be described later, are arranged two-dimensionally along a plane perpendicular to the Z-axis direction. In this example, the plurality of cell units are arranged on a straight line along the X-axis direction or the Y-axis direction. The cathode area 102 is a region in which a cathode electrode electrically connected to the avalanche photodiode disposed in the light-receiving area 101 is disposed. The cathode area 102 overlaps the light-receiving area 101 in the Z-axis direction.

The anode area 103 is a region in which an anode electrode (electrode layer 18 described later) electrically connected to the avalanche photodiode disposed in the light-receiving area 101 is disposed. The anode area 103 is located in a frame shape to surround the light-receiving area 101 and the cathode area 102 when viewed from the Z-axis direction. The cathode electrode disposed in the cathode area 102 and the anode electrode disposed in the anode area 103 are electrically connected to a substrate included in the photodetection element 1. Charge carriers generated in the avalanche photodiode of the light-receiving area 101 are transmitted as a current signal to the substrate via the cathode electrode and the anode electrode. The wire pad area 104 is a region in which an external connection pad electrically connected to the substrate is disposed. The current signal is sent out to the outside of the photodetection element 1 via the pad disposed in the wire pad area 104 after being processed, for example, in a circuit included in the substrate.

Next, the configuration of the photodetection element 1 will be described in more detail with reference to FIGS. 2 to 4. The photodetection element 1 includes a substrate 2, a semiconductor substrate 3, a plurality of insulating films 4, a layered structure 200, a plurality of lenses 7, a metal portion 10, an insulating film 11, an insulating layer 12, a plurality of quenching elements 13, a plurality of wiring layers 14, a plurality of wiring layers 15, a plurality of light-reflecting layers 16, a plurality of connection conductors 17, a plurality of electrode layers 18, a plurality of connection conductors 19, an insulating layer 21, a plurality of connection conductors 22, a plurality of electrode layers 23, a plurality of connection conductors 24, and a plurality of electrode layers 25. The layered structure 200 incudes an insulating layer 5 and a spacer layer 6.

The substrate 2 is a substrate on which an IC (integrated circuit) such as an ASIC is formed. The substrate 2 processes a current signal corresponding to charge carriers generated in avalanche photodiodes APD described later. In one example, the substrate 2 is formed in a rectangular plate shape. The substrate 2 includes a surface 2a and a surface 2b. The surface 2a and the surface 2b extend perpendicularly to the Z-axis direction. As illustrated in FIG. 1, in a region indicated by reference numeral 20 of the substrate 2, for example, a plurality of wirings for applying a reverse bias voltage to the avalanche photodiodes APD described later are formed. In FIG. 1, for convenience of explanation, the region 20 is hatched.

The semiconductor substrate 3 includes, for example, a substrate containing silicon (Si). For example, the semiconductor substrate 3 has a rectangular shape in plan view. For example, the rectangular shape includes a shape in which each corner is chamfered and a shape in which each corner is rounded. The semiconductor substrate 3 includes a surface 3a to be a light-incident surface and a surface 3b located opposite to the surface 3a. In the present embodiment, the surface 3b is located on a side opposite to the surface 3a in the Z-axis direction. As described above, the photodetection element 1 is a back-illuminated type optical semiconductor element. Therefore, in the present embodiment, the surface 3a includes a back surface of the semiconductor substrate 3, and the surface 3b includes a front surface of the semiconductor substrate 3. For example, in a configuration in which the surface 3a includes a first surface of the semiconductor substrate 3, the surface 3b includes a second surface of the semiconductor substrate 3.

The surface 3a and the surface 3b extend perpendicularly to the Z-axis direction. That is, in this example, the Z-axis direction is a direction perpendicular to the surface 3a. As described above, the surface 3a is a surface to be a light-incident surface. That is, light detected by the photodetection element 1 enters the inside of the semiconductor substrate 3 from the surface 3a. The surface 3b is located on a side opposite to the surface 3a in the Z-axis direction. The surface 3b is located closer to the substrate 2 than the surface 3a.

The semiconductor substrate 3 includes an epitaxial semiconductor layer 31, an epitaxial semiconductor layer 32, and a semiconductor layer 33. In the present disclosure, an epitaxial semiconductor layer refers to a semiconductor layer formed by epitaxial growth. The epitaxial semiconductor layer 31 includes the surface 3b. That is, the epitaxial semiconductor layer 31 includes the front surface of the semiconductor substrate 3.

The epitaxial semiconductor layer 31 includes an epitaxial semiconductor region 311, a plurality of semiconductor regions 312, a plurality of semiconductor regions 313, and a plurality of semiconductor regions 314. In the present embodiment, the epitaxial semiconductor region 311 is divided by a trench 40 described later. Therefore, it can also be said that the epitaxial semiconductor layer 31 includes a plurality of divided epitaxial semiconductor regions 311. Each epitaxial semiconductor region 311 is formed to cover a corresponding semiconductor region 312, semiconductor region 313, and semiconductor region 314.

The epitaxial semiconductor region 311 has a first conductivity type. The first conductivity type includes p-type. In the present embodiment, the epitaxial semiconductor region 311 includes a p-type epitaxial semiconductor region. The epitaxial semiconductor region 311 has an impurity concentration of, for example, 1.0×10¹³ cm⁻³ or more and 1.0×10¹⁷ cm₋₃ or less. The impurity concentration of the epitaxial semiconductor region 311 includes, for example, a concentration of p-type impurities.

In the epitaxial semiconductor layer 31, each of the plurality of semiconductor regions 312 is formed such that a surface thereof is along the surface 3b. The surface of the semiconductor region 312 constitutes a part of the surface 3b. That is, the semiconductor region 312 includes a part of the surface 3b. Each of the plurality of semiconductor regions 312 has, for example, a rectangular shape when viewed from the Z-axis direction.

The semiconductor region 312 has a second conductivity type different from the first conductivity type. The second conductivity type includes n-type. In the present embodiment, the semiconductor region 312 includes an n+-type semiconductor region. Here, “+” attached to the conductivity type indicates a high impurity concentration. The semiconductor region 312 has an impurity concentration of, for example, 1.0×10¹⁷ cm⁻³ or more and 1.0×10²¹ cm⁻³ or less. The impurity concentration of the semiconductor region 312 includes, for example, a concentration of n-type impurities.

In the photodetection element 1, each of the plurality of semiconductor regions 312 constitutes an avalanche photodiode APD together with the epitaxial semiconductor region 311. That is, the semiconductor substrate 3 has a plurality of avalanche photodiodes APD. In the present embodiment, a pair of epitaxial semiconductor region 311 and semiconductor region 312 corresponding to each other constitutes one avalanche photodiode APD.

Each of the plurality of semiconductor regions 313 is located between the epitaxial semiconductor region 311 and the corresponding semiconductor region 312. Each of the plurality of semiconductor regions 313 covers the corresponding semiconductor region 312 between the epitaxial semiconductor region 311 and the corresponding semiconductor region 312. That is, the epitaxial semiconductor region 311 covers the semiconductor region 312 via the semiconductor region 313.

The semiconductor region 313 has a first conductivity type. In the present embodiment, the semiconductor region 313 includes a p-type semiconductor region. The semiconductor region 313 has an impurity concentration of, for example, 1.0×10¹⁴ cm⁻³ or more and 1.0×10¹⁸ cm⁻³ or less. The impurity concentration of the semiconductor region 313 includes, for example, a concentration of p-type impurities.

Each of the plurality of semiconductor regions 314 is formed to surround the corresponding semiconductor region 312 when viewed from the Z-axis direction. In the present embodiment, each of the plurality of semiconductor regions 314 is formed to surround the corresponding semiconductor region 312 and semiconductor region 313 when viewed from the Z-axis direction. The semiconductor region 314 is a guard ring region. The semiconductor region 314 has a second conductivity type. The semiconductor region 314 includes an n-type semiconductor region. The semiconductor region 314 has an impurity concentration of, for example, 1.0×10¹⁵ cm⁻³ or more and 1.0×10¹⁹ cm⁻³ or less. The impurity concentration of the semiconductor region 314 includes, for example, a concentration of n-type impurities.

The epitaxial semiconductor layer 31 has a thickness T1. For example, the thickness T1 refers to a length of the epitaxial semiconductor layer 31 in the Z-axis direction. Here, the length of the epitaxial semiconductor layer 31 in the Z-axis direction refers to a distance from an interface between the epitaxial semiconductor region 311 and the epitaxial semiconductor layer 32 to the surface of the semiconductor region 312. As described above, in the present embodiment, the surface of the semiconductor region 312 constitutes a part of the surface 3b. Therefore, the length of the epitaxial semiconductor layer 31 in the Z-axis direction can also be referred to as a distance from the interface between the epitaxial semiconductor region 311 and the epitaxial semiconductor layer 32 to the surface 3b. The thickness T1 is, for example, 0.5 μm or more and 10 μm or less. In the present embodiment, the thickness T1 is 2 μm.

The epitaxial semiconductor layer 32 is disposed on the epitaxial semiconductor layer 31. The epitaxial semiconductor layer 32 is located on a side opposite to the surface 3b with respect to the epitaxial semiconductor layer 31. The epitaxial semiconductor layer 32 is disposed between the surface 3a and the epitaxial semiconductor region 311. The epitaxial semiconductor layer 32 is adjacent to the epitaxial semiconductor region 311 between the surface 3a and the epitaxial semiconductor region 311.

For example, in configuration in which the epitaxial semiconductor layer 31 includes a first epitaxial semiconductor layer, the epitaxial semiconductor layer 32 includes a second epitaxial semiconductor layer.

The epitaxial semiconductor layer 32 has a thickness T2. For example, the thickness T2 includes a length of the epitaxial semiconductor layer 32 in the Z-axis direction. The thickness T2 is, for example, 19.5 μm or more and 49.5 μm or less. In the present embodiment, the thickness T2 is 19 μm.

The epitaxial semiconductor layer 32 has a first conductivity type. In the present embodiment, the epitaxial semiconductor layer 32 includes a p-type epitaxial semiconductor layer. The epitaxial semiconductor layer 32 has an impurity concentration of, for example, 1.0×10¹² cm⁻³ or more and 1.0×10¹⁶ cm⁻³ or less. The impurity concentration of the epitaxial semiconductor layer 32 includes, for example, a concentration of p-type impurities.

The semiconductor layer 33 is disposed on the epitaxial semiconductor layer 32. The semiconductor layer 33 is located on a side opposite to the surface 3b with respect to the epitaxial semiconductor layer 32. The semiconductor layer 33 is disposed between the surface 3a and the epitaxial semiconductor layer 32. The semiconductor layer 33 is adjacent to the epitaxial semiconductor layer 32 between the surface 3a and the epitaxial semiconductor layer 32. The semiconductor layer 33 is formed such that a surface thereof is along the surface 3a. The surface of the semiconductor layer 33 constitutes a part of the surface 3a. That is, the semiconductor layer 33 includes a part of the surface 3a. In the present embodiment, the semiconductor substrate 3 includes only the epitaxial semiconductor layer 31, the epitaxial semiconductor layer 32, and the semiconductor layer 33. In the present embodiment, in the semiconductor substrate 3, the epitaxial semiconductor layer 31, the epitaxial semiconductor layer 32, and the semiconductor layer 33 are arranged in this order.

The semiconductor layer 33 has a first conductivity type. The semiconductor layer 33 includes a p+-type semiconductor layer. The semiconductor layer 33 has an impurity concentration of, for example, 1.0×10¹⁷ cm⁻³ or more and 1.0×10²¹ cm⁻³ or less. The impurity concentration of the semiconductor layer 33 includes, for example, a concentration of p-type impurities.

The semiconductor layer 33 has a thickness T3. For example, the thickness T3 includes a length of the semiconductor layer 33 in the Z-axis direction. The thickness T3 is, for example, 0.1 μm or more and 5 μm or less. In the present embodiment, the thickness T3 is 1.2 μm.

In the present embodiment, the semiconductor substrate 3 further includes a semiconductor layer 34, a semiconductor layer 35, a frame region 36, and a semiconductor layer 37.

The semiconductor layer 34 is formed outside the epitaxial semiconductor layer 31, the epitaxial semiconductor layer 32, and the semiconductor layer 33 when viewed from the Z-axis direction. The semiconductor layer 34 is continuous with the epitaxial semiconductor layer 32. In the present embodiment, the semiconductor layer 34 is continuous with the epitaxial semiconductor layer 32 between a bottom of a trench 40 described later and the surface 3a. In the present embodiment, the semiconductor layer 34 has the same thickness as the epitaxial semiconductor layer 32. That is, in the present embodiment, the semiconductor layer 34 has the thickness T2.

The semiconductor layer 34 has a first conductivity type. In the present embodiment, the semiconductor layer 34 includes a p-type semiconductor layer. The semiconductor layer 34 includes an epitaxial semiconductor layer. That is, the semiconductor layer 34 includes a p-type epitaxial semiconductor layer. The semiconductor layer 34 has an impurity concentration of, for example, 1.0×10¹² cm⁻³ or more and 1.0×10¹⁶ cm⁻³ or less. The impurity concentration of the semiconductor layer 34 includes, for example, a concentration of p-type impurities.

The semiconductor layer 35 is located on a side opposite to the surface 3a with respect to the semiconductor layer 34. The semiconductor layer 35 is disposed between the semiconductor layer 34 and the surface 3b. The semiconductor layer 35 is adjacent to the semiconductor layer 34 between the semiconductor layer 34 and the surface 3b. The semiconductor layer 35 is formed outside the epitaxial semiconductor layer 31, the epitaxial semiconductor layer 32, and the semiconductor layer 33 when viewed from the Z-axis direction. The semiconductor layer 35 is also divided from the epitaxial semiconductor layer 31, the epitaxial semiconductor layer 32, and the semiconductor layer 33 by the trench 40 described later. The semiconductor layer 35 is located to overlap a part of the semiconductor layer 34 in the Z-axis direction. The semiconductor layer 35 constitutes a part of the surface 3b. In the present embodiment, the semiconductor layer 35 has the same thickness as the epitaxial semiconductor layer 31. That is, in the present embodiment, the semiconductor layer 35 has the thickness T1.

The semiconductor layer 35 has a first conductivity type. In the present embodiment, the semiconductor layer 35 includes a p-type semiconductor layer. The semiconductor layer 35 includes an epitaxial semiconductor layer. That is, the semiconductor layer 35 includes a p-type epitaxial semiconductor layer. The semiconductor layer 35 has an impurity concentration of, for example, 1.0×10¹³ cm⁻³ or more and 1.0×10¹⁷ cm⁻³ or less. The impurity concentration of the semiconductor layer 35 includes, for example, a concentration of p-type impurities.

The frame region 36 is located on a side opposite to the surface 3a with respect to the semiconductor layer 34. The frame region 36 is disposed between the semiconductor layer 34 and the surface 3b. The frame region 36 is adjacent to the semiconductor layer 34 between the semiconductor layer 34 and the surface 3b. The frame region 36 is formed outside the semiconductor layer 35 when viewed from the Z-axis direction. That is, the frame region 36 is formed outside the epitaxial semiconductor layer 31, the epitaxial semiconductor layer 32, and the semiconductor layer 33 when viewed from the Z-axis direction. In the present embodiment, the frame region 36 is formed adjacent to the semiconductor layer 35.

The frame region 36 is located to overlap a part of the semiconductor layer 34 in the Z-axis direction. The frame region 36 is formed in a rectangular frame shape to surround the plurality of avalanche photodiodes APD when viewed from the Z-axis direction. The frame region 36 is formed continuously when viewed from the Z-axis direction. The frame region 36 constitutes a part of the surface 3b. The frame region 36 is electrically connected to the epitaxial semiconductor layer 31 and the epitaxial semiconductor layer 32 via the semiconductor layer 34, the semiconductor layer 37, and the semiconductor layer 33. The frame region 36 is electrically connected to a power supply circuit of the substrate 2 via the electrode layer 18, the connection conductor 19, the connection conductor 24, and the electrode layer 25 described later.

The frame region 36 has a first conductivity type. In the present embodiment, the frame region 36 includes a p-type semiconductor region. The frame region 36 has an impurity concentration of, for example, 1.0×10¹⁷ cm⁻³ or more and 1.0×10²¹ cm⁻³ or less. The impurity concentration of the frame region 36 includes, for example, a concentration of p-type impurities.

The semiconductor layer 37 is formed outside the epitaxial semiconductor layer 31, the epitaxial semiconductor layer 32, and the semiconductor layer 33 when viewed from the Z-axis direction. The semiconductor layer 37 is formed in a frame shape to surround a plurality of frame portions 41 when viewed from the Z-axis direction. In the present embodiment, the semiconductor layer 37 is continuous with the semiconductor layer 33. The semiconductor layer 37 is disposed on the semiconductor layer 34. The semiconductor layer 37 is located on a side opposite to the surface 3b with respect to the semiconductor layer 34. The semiconductor layer 37 is disposed between the surface 3a and the semiconductor layer 34. The semiconductor layer 37 is adjacent to the semiconductor layer 34 between the surface 3a and the semiconductor layer 34. The semiconductor layer 37 is formed such that a surface thereof is along the surface 3a. The surface of the semiconductor layer 37 constitutes a part of the surface 3a. That is, the semiconductor layer 37 includes a part of the surface 3a. In the present embodiment, the surface of the semiconductor layer 33 and the surface of the semiconductor layer 37 constitute the surface 3a. In the present embodiment, the semiconductor layer 37 has the same thickness as the semiconductor layer 33. That is, in the present embodiment, the semiconductor layer 37 has the thickness T3.

The semiconductor layer 37 has a first conductivity type. In the present embodiment, the semiconductor layer 37 includes a p+-type semiconductor layer. The semiconductor layer 37 has an impurity concentration of, for example, 1.0×10¹⁷ cm⁻³ or more and 1.0×10²¹ cm⁻³ or less. The impurity concentration of the semiconductor layer 37 includes, for example, a concentration of p-type impurities.

The semiconductor substrate 3 is provided with a trench 40. The trench 40 extends in the Z-axis direction. That is, a depth direction of the trench 40 includes a thickness direction of the semiconductor substrate 3. The trench 40 opens at the surface 3b and reaches at least the epitaxial semiconductor layer 32. That is, the trench 40 penetrates the epitaxial semiconductor layer 31. In the present embodiment, the trench 40 reaches the epitaxial semiconductor layer 32 and does not reach the semiconductor layer 33. That is, a bottom of the trench 40 is located inside the epitaxial semiconductor layer 32.

The trench 40 is provided in a mesh shape. In FIG. 4, for convenience of explanation, the trench 40 is hatched. In the present embodiment, the trench 40 includes a plurality of frame portions 41 extending in a frame shape when viewed from the Z-axis direction. Each of the plurality of frame portions 41 extends, for example, in a rectangular frame shape. More specifically, each frame portion 41 includes a pair of first portions 411 extending along the X-axis direction and a pair of second portions 412 extending along the Y-axis direction.

Inside each frame portion 41, one epitaxial semiconductor region 311, one semiconductor region 312, one semiconductor region 313, one semiconductor region 314, the epitaxial semiconductor layer 32, and the semiconductor layer 33 are located. In the present embodiment, the trench 40 extends to separate the plurality of epitaxial semiconductor regions 311 from each other.

Inside each frame portion 41, one avalanche photodiode APD is located. The trench 40 extends to separate the plurality of avalanche photodiodes APD from each other when viewed from the Z-axis direction. Each frame portion 41 is formed to surround the corresponding avalanche photodiode APD when viewed from the Z-axis direction.

The plurality of insulating films 4 are formed on the surface 3b at positions corresponding to the epitaxial semiconductor regions 311. Each insulating film 4 is formed to cover a surface of the corresponding epitaxial semiconductor region 311 that constitutes the surface 3b. The insulating film 4 is formed of, for example, a silicon nitride film (LP—SiN). The insulating film 4 can protect the epitaxial semiconductor region 311 in a manufacturing process of the photodetection element 1 and reduce variation in characteristics of the avalanche photodiode APD.

The layered structure 200 is formed on the surface 3a of the semiconductor substrate 3. That is, the layered structure 200 is formed on the semiconductor layer 33. As described above, the layered structure 200 has the insulating layer 5 and the spacer layer 6. The layered structure 200 has a surface 200a and a surface 200b. The surface 200a is located on a side opposite to the surface 200b in the Z-axis direction. The surface 200a is a surface on a side opposite to the surface 3a in the layered structure 200. The surface 200b is a surface on a side closer to the surface 3a in the layered structure 200.

The insulating layer 5 is formed on the surface 3a of the semiconductor substrate 3. The insulating layer 5 is formed directly on the surface 3a. The insulating layer 5 is in contact with the surface 3a. As illustrated in FIG. 3, the insulating layer 5 includes a main surface 5a and a main surface 5b. The main surface 5a is a surface on a side opposite to the semiconductor substrate 3 in the insulating layer 5, and the main surface 5b is a surface on a side closer to the semiconductor substrate 3 in the insulating layer 5. The main surface 5b constitutes the surface 200b of the layered structure 200. The insulating layer 5 is formed to cover the semiconductor layer 33 and the semiconductor layer 37. The insulating layer 5 is formed of an electrically insulating material. In one example, the insulating layer 5 may be a silicon oxide film or a silicon nitride film. The silicon oxide film may be, for example, a SiO₂ film. The silicon nitride film may be, for example, a SiN film. In the present embodiment, the insulating layer 5 is a SiN film, and the SiN film functions as an anti-reflection (AR) film.

The spacer layer 6 is formed on the surface 3a of the semiconductor substrate 3. In the present embodiment, the spacer layer 6 is formed above the surface 3a, with the insulating layer 5 interposed therebetween. The spacer layer 6 is formed directly on the insulating layer 5. The spacer layer 6 is in contact with the main surface 5a of the insulating layer 5. As illustrated in FIG. 2, the spacer layer 6 includes a surface 6a and a surface 6b. The surface 6a is a surface on a side opposite to the insulating layer 5 in the spacer layer 6, and the surface 6b is a surface on a side closer to the insulating layer 5 in the spacer layer 6. That is, the surface 6a is located on a side opposite to the surface 6b in the Z-axis direction. The surface 6a constitutes the surface 200a of the layered structure 200. The spacer layer 6 is formed of an electrically insulating material. The spacer layer 6 is, for example, a resin layer formed of a resin material. The spacer layer 6 may be formed of a material other than resin.

The spacer layer 6 has a thickness T4. For example, the thickness T4 includes a length of the spacer layer 6 in the Z-axis direction. The thickness T4 is, for example, 0.1 μm or more and 10 μm or less. In the present embodiment, the thickness T4 is 1 μm.

Each of the plurality of lenses 7 is disposed on the surface 3a to overlap a corresponding semiconductor region 312 among the plurality of semiconductor regions 312 when viewed from the Z-axis direction. That is, each of the plurality of lenses 7 is disposed to overlap the corresponding avalanche photodiode APD in the Z-axis direction. The lens 7 condenses light incident on the lens 7 onto the avalanche photodiode APD.

In the present embodiment, the plurality of lenses 7 are disposed on the layered structure 200. The lens 7 is formed directly on the spacer layer 6 of the layered structure 200. The lens 7 is in contact with the surface 6a of the spacer layer 6. The lens 7 is disposed above the surface 3a, with the spacer layer 6 interposed therebetween. That is, the spacer layer 6 is provided between the plurality of lenses 7 and the surface 3a. The plurality of lenses 7 are arranged two-dimensionally along a plane perpendicular to the Z-axis direction.

The lens 7 has a surface 7a and a surface 7b. The surface 7a is a surface on a side opposite to the spacer layer 6 in the lens 7. The surface 7a is a curved surface protruding toward a side opposite to the spacer layer 6. The surface 7b is a surface on a side closer to the spacer layer 6 in the lens 7. The surface 7b is a flat surface extending perpendicularly to the Z-axis direction. When viewed from the Z-axis direction, an outer edge 7c of each of the plurality of lenses 7 overlaps the trench 40. The outer edge 7c is located outside an outer edge of the epitaxial semiconductor region 311. The outer edge 7c has, for example, a rectangular shape.

The lens 7 has a thickness T5. For example, the thickness T5 includes a longest distance between the surface 7a and the surface 7b in the Z-axis direction. The thickness T5 is, for example, 1 μm or more and 25 μm or less. In the present embodiment, the thickness T5 is 10 μm.

The metal portion 10 is formed inside the trench 40. The metal portion 10 is disposed to separate adjacent avalanche photodiodes APD from each other. When viewed from the Z-axis direction, the metal portion 10 extends along the trench 40. The metal portion 10 is formed of, for example, tungsten.

The insulating film 11 is formed inside the trench 40. The insulating film 11 is formed between an inner surface of the trench 40 and the metal portion 10. The insulating film 11 is formed of an electrically insulating material. In one example, the insulating film 11 is an oxide film. The oxide film is, for example, a SiO₂ film. The insulating film 11 electrically insulates the epitaxial semiconductor layer 31 and the metal portion 10 from each other. The insulating film 11 electrically insulates the epitaxial semiconductor layer 32 and the metal portion 10 from each other.

The insulating layer 12 is formed on the surface 3b of the semiconductor substrate 3. The insulating layer 12 is formed directly on the surface 3b. The insulating layer 12 is in contact with the surface 3b. The insulating layer 12 is formed of an electrically insulating material. In one example, the insulating layer 12 is an oxide film. The oxide film is, for example, a SiO₂ film.

The plurality of quenching elements 13 are located inside the insulating layer 12. The plurality of quenching elements 13 are located on a side closer to the surface 3b with respect to the semiconductor substrate 3. Each of the plurality of quenching elements 13 is electrically connected to the corresponding semiconductor region 312 and light-reflecting layer 16.

In one example, the quenching element 13 is a quenching resistor formed in a frame plate shape having a thickness along the Z-axis direction. In this example, the quenching element 13 is formed in a substantially rectangular frame shape when viewed from the Z-axis direction. In the present embodiment, one end of the quenching element 13 is connected to the semiconductor region 312 via the wiring layer 14. The quenching element 13 is connected in series with the semiconductor region 312 (avalanche photodiode APD). The other end of the quenching element 13 is electrically connected to the light-reflecting layer 16 via the wiring layer 15.

The plurality of light-reflecting layers 16 are provided on the surface 3b. Each of the plurality of light-reflecting layers 16 is disposed on the surface 3b to oppose the corresponding semiconductor region 312 among the plurality of semiconductor regions 312. Each of the plurality of light-reflecting layers 16 reflects light incident from the surface 3a. Each of the plurality of light-reflecting layers 16 reflects light incident from the surface 3a onto the corresponding semiconductor region 312.

In the present embodiment, as illustrated in FIG. 3, each of the plurality of light-reflecting layers 16 is disposed inside the insulating layer 12 to oppose the corresponding semiconductor region 312 in the Z-axis direction. That is, in the present embodiment, the plurality of light-reflecting layers 16 are located inside the insulating layer 12. Each light-reflecting layer 16 overlaps at least a part of the corresponding semiconductor region 312 in the Z-axis direction. Each light-reflecting layer 16 is located between the surface 3b and the quenching element 13 in the Z-axis direction. In one example, the light-reflecting layer 16 has a substantially rectangular shape when viewed from the Z-axis direction. The light-reflecting layer 16 is formed of a metal material such as aluminum.

The plurality of connection conductors 17 are provided inside the insulating layer 12. The plurality of connection conductors 17 are located on a side closer to the substrate 2 with respect to the plurality of light-reflecting layers 16. Each connection conductor 17 is formed in a columnar shape (for example, a cylindrical shape) having a central axis along the Z-axis direction. Each connection conductor 17 is electrically connected to the corresponding light-reflecting layer 16 and a corresponding connection conductor 22 among a plurality of connection conductors 22 described later. The connection conductor 17 is formed of a metal material such as copper.

The plurality of electrode layers 18 are provided inside the insulating layer 12. The plurality of electrode layers 18 are located on a side closer to the surface 3b with respect to the semiconductor substrate 3. Each of the plurality of electrode layers 18 is electrically connected to the frame region 36 via wiring or the like. The electrode layer 18 extends, for example, in the X-axis direction and opposes the frame region 36 in the Z-axis direction. The electrode layer 18 is formed of a metal material such as aluminum.

The plurality of connection conductors 19 are provided inside the insulating layer 12. The plurality of connection conductors 19 are located on a side closer to the substrate 2 with respect to the plurality of electrode layers 18. Each connection conductor 19 is formed in a columnar shape (for example, a cylindrical shape) having a central axis along the Z-axis direction. Each connection conductor 19 is electrically connected to the corresponding electrode layer 18 and a corresponding connection conductor 24 among a plurality of connection conductors 24 described later. The connection conductor 19 is formed of a metal material such as copper.

The insulating layer 21 is formed on the surface 2a of the substrate 2. The insulating layer 21 is formed directly on the surface 2a. The insulating layer 21 is in contact with the surface 2a. The insulating layer 21 is also in contact with a surface 12b on a side opposite to the semiconductor substrate 3 in the insulating layer 12. The insulating layer 21 and the insulating layer 12 are stacked on the surface 2a in this order. The insulating layer 21 is formed of an electrically insulating material. In one example, the insulating layer 21 is an oxide film. The oxide film is, for example, a SiO₂ film.

The plurality of connection conductors 22 are formed inside the insulating layer 21. Each connection conductor 22 is formed in a columnar shape (for example, a cylindrical shape) having a central axis along the Z-axis direction. Each connection conductor 22 is electrically connected to the corresponding connection conductor 17 and a corresponding electrode layer 23 among a plurality of electrode layers 23 described later. The connection conductor 22 is formed of a metal material such as copper.

The plurality of electrode layers 23 are formed inside the insulating layer 21. The plurality of electrode layers 23 are located on a side closer to the substrate 2 with respect to the plurality of connection conductors 22. Each of the plurality of electrode layers 23 is electrically connected to the corresponding connection conductor 22 and the substrate 2. The electrode layer 23 extends perpendicularly to the Z-axis direction. The electrode layer 23 is formed of a metal material such as aluminum.

The plurality of connection conductors 24 are formed inside the insulating layer 21. Each connection conductor 24 is formed in a columnar shape (for example, a cylindrical shape) having a central axis along the Z-axis direction. Each connection conductor 24 is electrically connected to the corresponding connection conductor 19 and a corresponding electrode layer 25 among a plurality of electrode layers 25 described later. The connection conductor 24 is formed of a metal material such as copper.

The plurality of electrode layers 25 are formed inside the insulating layer 21. The plurality of electrode layers 25 are located on a side closer to the substrate 2 with respect to the plurality of connection conductors 24. Each of the plurality of electrode layers 25 is electrically connected to the corresponding connection conductor 24 and the substrate 2. The electrode layer 25 extends perpendicularly to the Z-axis direction. The electrode layer 25 is formed of a metal material such as aluminum.

Next, a relationship among the thickness T1, the thickness T2, the thickness T3, the thickness T4, and the thickness T5 in the photodetection element 1 will be described. For example, the thickness T1, the thickness T2, and the thickness T3 may be different from each other. In the present embodiment, the thickness T2 is greater than the thickness T1. That is, the epitaxial semiconductor layer 32 has the thickness T2 greater than the thickness T1 of the epitaxial semiconductor layer 31. A ratio of the thickness T2 to the thickness T1 may be, for example, 200% or more.

In the present embodiment, the thickness T2 is greater than the thickness T3. That is, the epitaxial semiconductor layer 32 may have the thickness T2 greater than the thickness T3 of the semiconductor layer 33. A ratio of the thickness T2 to the thickness T3 may be, for example, 390% or more.

In the present embodiment, the thickness T1 is greater than the thickness T3. That is, the epitaxial semiconductor layer 31 may have the thickness T1 greater than the thickness T3 of the semiconductor layer 33. A ratio of the thickness T1 to the thickness T3 may be, for example, 110% or more. Thus, in the present embodiment, the thickness T1, the thickness T2, and the thickness T3 satisfy a relationship of T2>T1>T3.

A sum of the thickness T1 and the thickness T2 may be, for example, 20 μm or more, or may be 30 μm or more. The sum of the thickness T1 and the thickness T2 may be, for example, 50 μm or less, or may be 40 μm or less. A sum of the thickness T1, the thickness T2, and the thickness T3 may be, for example, 20 μm or more, or may be 40 μm or more. The sum of the thickness T1, the thickness T2, and the thickness T3 may be, for example, 60 μm or less, or may be 50 μm or less.

In the present embodiment, the thickness T4 and the thickness T5 may be different from the thickness T1, the thickness T2, and the thickness T3. In the example illustrated in FIG. 3, the thickness T4 is smaller than the thickness T1, the thickness T2, and the thickness T3. The thickness T4 may be equal to or greater than the thickness T1, may be equal to or greater than the thickness T2, or may be equal to or greater than the thickness T3. In the example illustrated in FIG. 3, the thickness T5 is greater than the thickness T1 and the thickness T3, and is smaller than the thickness T2. The thickness T5 may be equal to or less than the thickness T1, may be equal to or less than the thickness T3, or may be equal to or greater than the thickness T2.

A sum of the thickness T4 and the thickness T5 may be, for example, 10 μm or more, or may be 30 μm or more. The sum of the thickness T4 and the thickness T5 may be, for example, 25 μm or less, or may be 35 μm or less.

The sum of the thickness T1 and the thickness T2 may be twice or more the sum of the thickness T4 and the thickness T5, or may be five times or more. The sum of the thickness T1 and the thickness T2 may be four times or less the sum of the thickness T4 and the thickness T5, or may be three times or less. A sum of the thickness T1, the thickness T2, and the thickness T3 may be greater than twice the sum of the thickness T4 and the thickness T5, or may be five times or more. The sum of the thickness T1, the thickness T2, and the thickness T3 may be seven times or less the sum of the thickness T4 and the thickness T5, or may be six times or less.

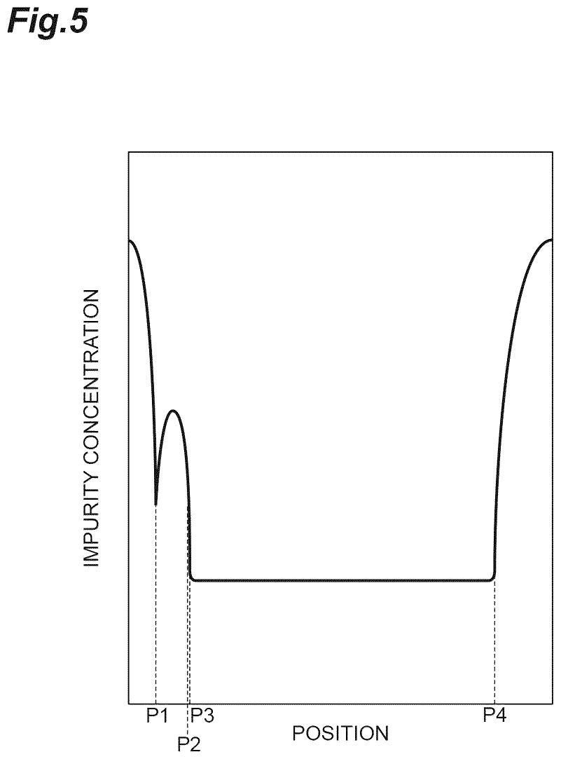

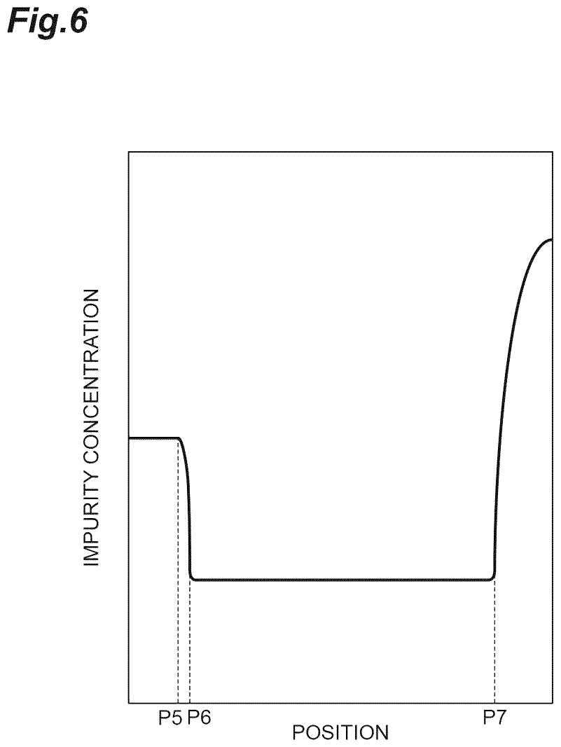

Next, a change in impurity concentration in the photodetection element 1 will be described with reference to FIGS. 5 and 6. FIG. 5 is a diagram illustrating an example of a change in impurity concentration in the photodetection element illustrated in FIG. 1. FIG. 6 is a diagram illustrating another example of a change in impurity concentration in the photodetection element illustrated in FIG. 1. In FIGS. 5 and 6, the horizontal axis indicates a position in the Z-axis direction of the semiconductor substrate 3, and the vertical axis indicates an impurity concentration at a corresponding position on a logarithmic scale. In FIGS. 5 and 6, moving in a positive direction of the horizontal axis indicates approaching the surface 3a, and moving in a negative direction of the horizontal axis indicates approaching the surface 3b.

First, a change in impurity concentration in the photodetection element 1 at a position where the avalanche photodiode APD is provided will be described. As illustrated in FIG. 5, the impurity concentration in the photodetection element 1 at the position where the avalanche photodiode APD is provided changes with respect to the Z-axis direction. That is, in the photodetection element 1, the impurity concentration changes with respect to the thickness direction of the semiconductor substrate 3. Here, the position where the avalanche photodiode APD is provided refers to a position overlapping the epitaxial semiconductor region 311 and the semiconductor region 312 when the photodetection element 1 is viewed from the Z-axis direction.

In FIG. 5, a region between a position P1 and a position P2 corresponds to the semiconductor region 313. A region between the position P2 and a position P3 corresponds to the epitaxial semiconductor region 311. A region between the position P3 and a position P4 corresponds to the epitaxial semiconductor layer 32. A region from the position P4 corresponds to the semiconductor layer 33.

As illustrated in FIG. 5, at the position where the avalanche photodiode APD is provided, the impurity concentration of the epitaxial semiconductor region 311 is higher than the impurity concentration of the epitaxial semiconductor layer 32. For example, a ratio of the impurity concentration of the epitaxial semiconductor region 311 to the impurity concentration of the epitaxial semiconductor layer 32 may be 110% or more.

The impurity concentration of the semiconductor region 313 is higher than the impurity concentration of the epitaxial semiconductor region 311 and the impurity concentration of the epitaxial semiconductor layer 32. For example, a ratio of the impurity concentration of the semiconductor region 313 to the impurity concentration of the epitaxial semiconductor region 311 may be 110% or more. For example, a ratio of the impurity concentration of the semiconductor region 313 to the impurity concentration of the epitaxial semiconductor layer 32 may be 110% or more.

The impurity concentration of the semiconductor layer 33 is higher than the impurity concentration of the epitaxial semiconductor layer 32. For example, a ratio of the impurity concentration of the semiconductor layer 33 to the impurity concentration of the epitaxial semiconductor layer 32 may be 110% or more.

The impurity concentration of the semiconductor region 312 is higher than the impurity concentration of the epitaxial semiconductor layer 32. For example, a ratio of the impurity concentration of the semiconductor region 312 to the impurity concentration of the epitaxial semiconductor layer 32 may be 110% or more. Furthermore, the impurity concentration of the semiconductor region 312 may be higher than the impurity concentration of the semiconductor region 314. For example, a ratio of the impurity concentration of the semiconductor region 312 to the impurity concentration of the semiconductor region 314 may be 110% or more.

Next, a change in impurity concentration in the photodetection element 1 at a position where the avalanche photodiode APD is not provided will be described. As illustrated in FIG. 6, even at the position where the avalanche photodiode APD is not provided, the impurity concentration in the photodetection element 1 changes with respect to the Z-axis direction. Here, the position where the avalanche photodiode APD is not provided refers to a position that does not overlap the epitaxial semiconductor region 311 and the semiconductor region 312 when the photodetection element 1 is viewed from the Z-axis direction.

In FIG. 6, a region between a position P5 and a position P6 corresponds to the epitaxial semiconductor region 311. A region between the position P6 and a position P7 corresponds to the epitaxial semiconductor layer 32. A region from the position P7 corresponds to the semiconductor layer 33.

As illustrated in FIG. 6, even at the position where the avalanche photodiode APD is not provided, the impurity concentration of the epitaxial semiconductor region 311 is higher than the impurity concentration of the epitaxial semiconductor layer 32. The ratio of the impurity concentration of the epitaxial semiconductor region 311 to the impurity concentration of the epitaxial semiconductor layer 32 may be, for example, the same as the ratio at the position where the avalanche photodiode APD is provided. The impurity concentration of the semiconductor layer 33 is higher than the impurity concentration of the epitaxial semiconductor layer 32. The ratio of the impurity concentration of the semiconductor layer 33 to the impurity concentration of the epitaxial semiconductor layer 32 may be, for example, the same as the ratio at the position where the avalanche photodiode APD is provided.

### Method for Manufacturing Photodetection Element

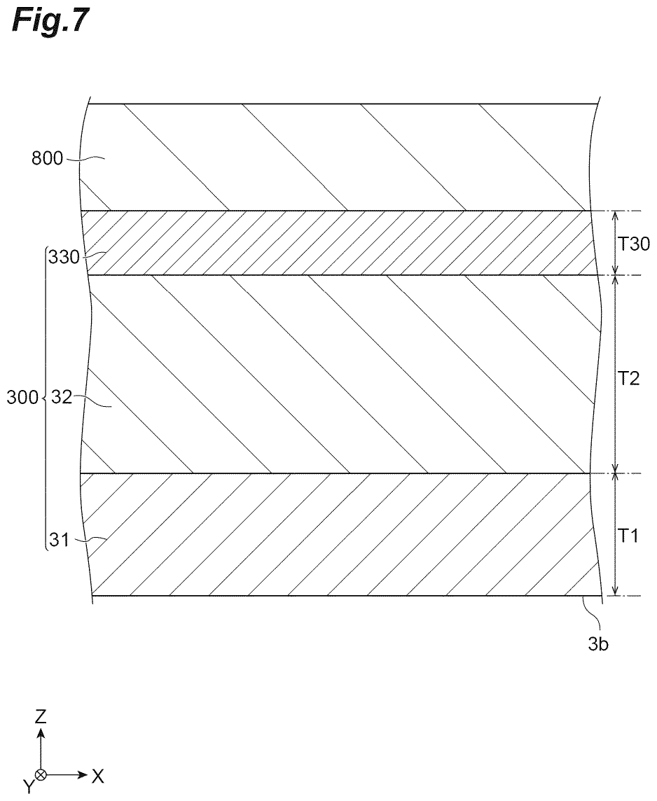

Next, a method for manufacturing the photodetection element 1 will be described with reference to FIGS. 7 to 12. FIGS. 7 to 12 are diagrams for explaining the method for manufacturing the photodetection element illustrated in FIG. 1. First, the semiconductor substrate 3 is prepared. In the present manufacturing method, for example, the semiconductor substrate 3 is prepared as follows. First, as illustrated in FIG. 7, a stacked body including a semiconductor substrate 300 and a semiconductor layer 800 is prepared. The semiconductor substrate 300 is a semiconductor substrate that becomes the semiconductor substrate 3 through a manufacturing process of the photodetection element 1. The semiconductor layer 800 is, for example, a bulk layer.

The semiconductor substrate 300 includes the epitaxial semiconductor layer 31, the epitaxial semiconductor layer 32, and a semiconductor layer 330. The semiconductor layer 330 is a layer that becomes the semiconductor layer 33 through the manufacturing process of the photodetection element 1. In the present manufacturing method, for example, the semiconductor substrate 300 including the epitaxial semiconductor layer 31, the epitaxial semiconductor layer 32, and the semiconductor layer 330 is prepared as follows.

First, the semiconductor layer 330 is formed. The semiconductor layer 330 is formed on the semiconductor layer 800, for example, by epitaxial growth. Alternatively, the semiconductor layer 330 may be formed on the semiconductor layer 800 by implantation of impurities of the first conductivity type. The semiconductor layer 330 is formed, for example, to have a thickness T30 greater than the thickness T3.

Next, the epitaxial semiconductor layer 32 is formed. In the present manufacturing method, the epitaxial semiconductor layer 32 is formed on the semiconductor layer 330. The epitaxial semiconductor layer 32 is formed by epitaxial growth to have the thickness T2.

Next, the epitaxial semiconductor layer 31 including the surface 3b is formed. In the present manufacturing method, the epitaxial semiconductor layer 31 is formed on the epitaxial semiconductor layer 32. The epitaxial semiconductor layer 31 is formed by epitaxial growth to have an impurity concentration higher than the impurity concentration of the epitaxial semiconductor layer 32. Furthermore, the epitaxial semiconductor layer 31 is formed to have the thickness T1. In the present manufacturing method, the epitaxial semiconductor layer 31 and the epitaxial semiconductor layer 32 are formed such that a sum of the thickness T1 and the thickness T2 is 20 μm or more and 50 μm or less. Here, the epitaxial semiconductor region 311, the plurality of semiconductor regions 312, the plurality of semiconductor regions 313, and the plurality of semiconductor regions 314 are not formed in the epitaxial semiconductor layer 31 formed when preparing the semiconductor substrate 300.

In the present manufacturing method, the epitaxial semiconductor layer 31 is formed to be adjacent to the epitaxial semiconductor layer 32 on a side opposite to the surface 3a. That is, it can be said that the epitaxial semiconductor layer 32 formed in the present manufacturing method is adjacent to the epitaxial semiconductor layer 31 between the surface 3a and the epitaxial semiconductor layer 31. In the present manufacturing method, the semiconductor substrate 300 including the epitaxial semiconductor layer 31, the epitaxial semiconductor layer 32, and the semiconductor layer 330 is thus prepared.

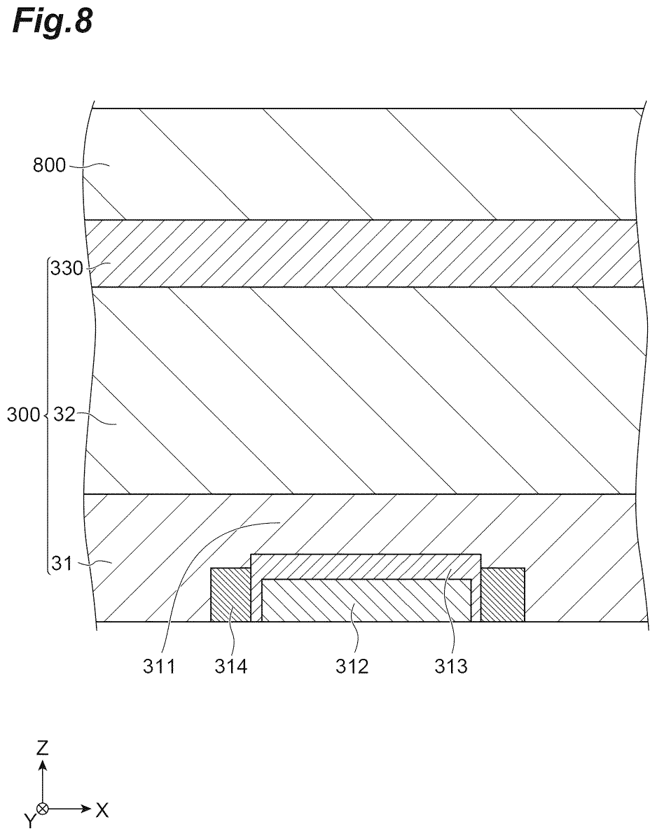

Next, as illustrated in FIG. 8, the plurality of semiconductor regions 312 are formed in the epitaxial semiconductor layer 31. The plurality of semiconductor regions 312 are formed by implanting impurities of a second conductivity type different from the first conductivity type, which is the conductivity type of the epitaxial semiconductor layer 31, into the epitaxial semiconductor layer 31 from the surface 3b side. In the present manufacturing method, a region where the impurities implanted into the epitaxial semiconductor layer 31 are diffused becomes the semiconductor region 312, and a remaining portion of the epitaxial semiconductor layer 31 where the impurities are not diffused becomes the epitaxial semiconductor region 311.

In the present manufacturing method, the plurality of semiconductor regions 313 and the plurality of semiconductor regions 314 are formed before the formation of the epitaxial semiconductor region 311 and the plurality of semiconductor regions 312. For example, the plurality of semiconductor regions 313 may be formed by implanting impurities of the first conductivity type into the epitaxial semiconductor layer 31 from the surface 3b side. For example, the plurality of semiconductor regions 314 may be formed by implanting impurities of the second conductivity type into the epitaxial semiconductor layer 31 from the surface 3b side. In this example, the impurities for forming the plurality of semiconductor regions 312 may be implanted into the semiconductor region 313 from the surface 3b side.

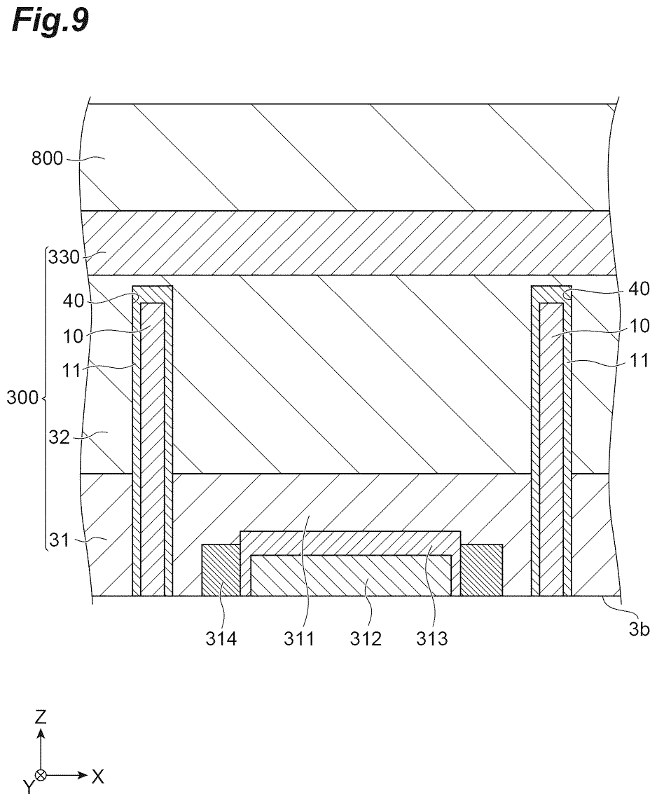

After the epitaxial semiconductor region 311 and the semiconductor region 312 are formed, the trench 40 is provided. The trench 40 is provided to surround the semiconductor region 312 when viewed from the Z-axis direction. The trench 40 is provided in the semiconductor substrate 300, for example, by etching. In one example, the trench 40 is provided from the surface 3b toward the surface 3a. That is, in this example, the trench 40 extending in the Z-axis direction is provided. In one example, as illustrated in FIG. 9, the trench 40 is provided to reach the epitaxial semiconductor layer 32 from the surface 3b in a direction from the surface 3b toward the surface 3a.

In the present manufacturing method, after the trench 40 is provided, the metal portion 10 and the insulating film 11 are formed inside the trench 40. In this example, the metal portion 10 is formed inside the trench 40 to extend along the trench 40 when viewed from the Z-axis direction. The insulating film 11 is formed between the inner surface of the trench 40 and the metal portion 10.

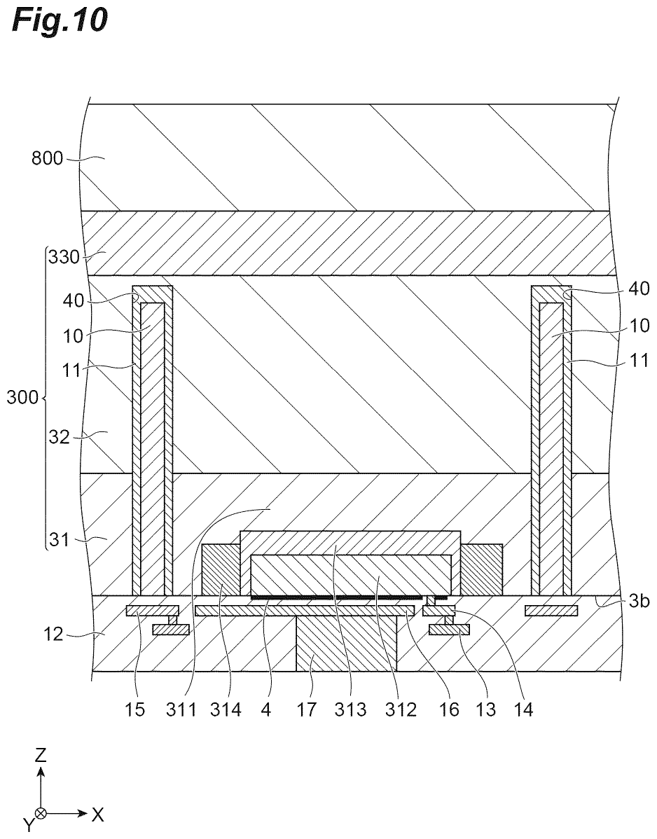

Next, as illustrated in FIG. 10, the insulating layer 12 is formed on the surface 3b of the semiconductor substrate 300. The insulating layer 12 is formed directly on the surface 3b. In the present manufacturing method, the insulating layer 12 having the plurality of quenching elements 13, the plurality of wiring layers 14, the plurality of wiring layers 15, the plurality of light-reflecting layers 16, and the plurality of connection conductors 17 formed therein is formed on the surface 3b. When forming the insulating layer 12, alignment of the insulating layer 12 and the semiconductor substrate 300 is performed such that each of the plurality of light-reflecting layers 16 opposes the corresponding semiconductor region 312 among the plurality of semiconductor regions 312 on the surface 3b. In one example, after the insulating layer 12 is formed, a planarization process may be performed on a surface of the insulating layer 12 on a side opposite to the semiconductor substrate 300. The planarization process may be, for example, Chemical Mechanical Polishing (CMP).

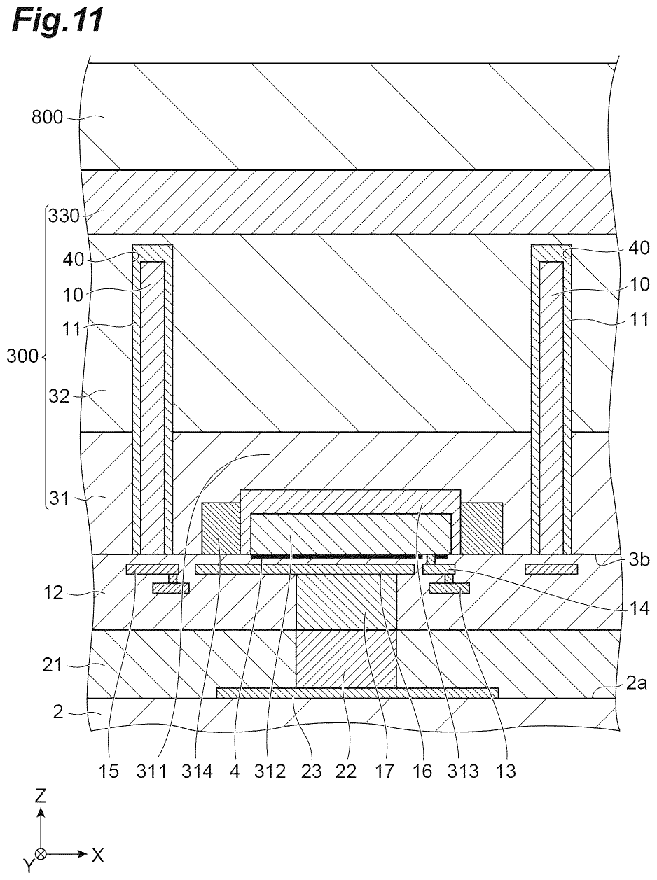

Next, as illustrated in FIG. 11, a stacked body of the substrate 2 and the insulating layer 21 is prepared, and the insulating layer 12 and the insulating layer 21 are bonded to each other. In one example, when bonding the insulating layer 12 and the insulating layer 21 to each other, alignment of the insulating layer 12 and the insulating layer 21 is performed such that the connection conductor 17 in the insulating layer 12 and the connection conductor 22 in the insulating layer 21 are connected to each other, and the connection conductor 19 in the insulating layer 12 and the connection conductor 24 in the insulating layer 21 are connected to each other.

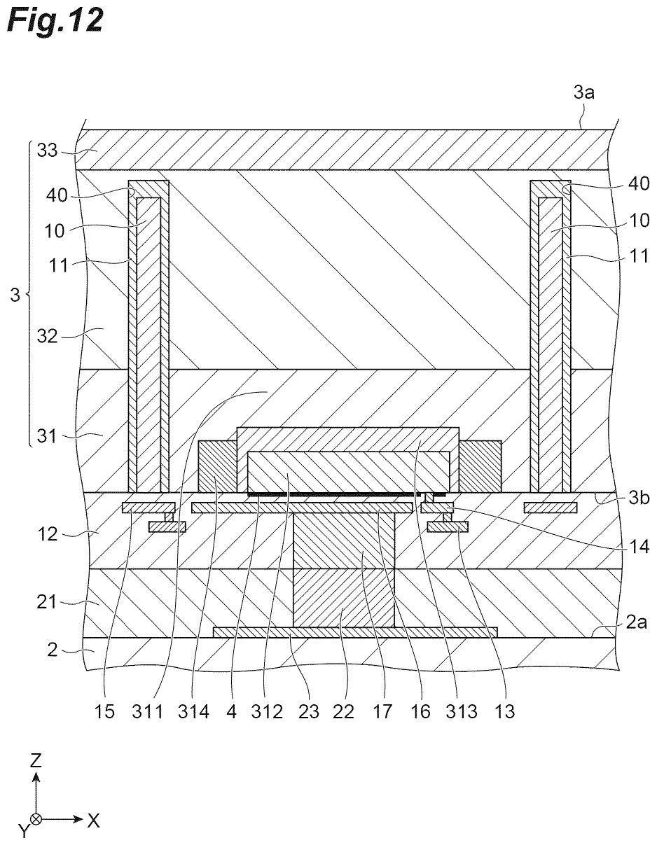

Next, as illustrated in FIG. 12, the semiconductor layer 800 is removed. In one example, the semiconductor layer 800 may be removed by polishing the semiconductor layer 800. The polishing of the semiconductor layer 800 may be performed, for example, by chemical mechanical polishing. In the present manufacturing method, a part of the semiconductor layer 330 is removed together with the semiconductor layer 800. That is, in the present manufacturing method, the semiconductor layer 330 is thinned. In the present manufacturing method, the thinned semiconductor layer 330 becomes the semiconductor layer 33. In one example, the thinning of the semiconductor layer 330 is performed until the thickness T30 of the semiconductor layer 330 becomes the thickness T3. In the present manufacturing method, the semiconductor substrate 3 is thus prepared.

Next, as illustrated in FIGS. 2 and 3, the plurality of lenses 7 are provided on the surface 3a. In the present manufacturing method, for example, the plurality of lenses 7 are provided as follows. First, the insulating layer 5 is formed on the surface 3a of the prepared semiconductor substrate 3. Next, the spacer layer 6 is formed on the insulating layer 5. Next, the plurality of lenses 7 are provided on the spacer layer 6. As a result, the plurality of lenses 7 are provided on the surface 3a. At this time, each of the plurality of lenses 7 is provided on the surface 3a to overlap the corresponding semiconductor region 312 among the plurality of semiconductor regions 312 when viewed from the Z-axis direction. Through the above processes, the photodetection element 1 is manufactured.

### Effects

Here, in a photodetection element, the detection efficiency, which indicates the number of detected photons relative to the number of incident photons, is affected by the above-described quantum efficiency and avalanche probability. Specifically, when the quantum efficiency or the avalanche probability increases, the detection efficiency in the photodetection element increases.

In the photodetection element 1, the epitaxial semiconductor layer 32 has the thickness T2 greater than the thickness T1 of the epitaxial semiconductor layer 31, and the sum of the thickness T1 and the thickness T2 is 20 μm or more and 50 μm or less. In the configuration in which the relationship between the thickness T1 and the thickness T2 satisfies the above-described relationship, the length of the optical path in the photodetection element 1 can be increased compared to a configuration in which the semiconductor substrate 3 includes a single epitaxial semiconductor layer. Therefore, the photodetection element 1 improves the quantum efficiency, which indicates the probability that incident light generates carriers.

In the photodetection element 1, the epitaxial semiconductor region 311 has an impurity concentration higher than the impurity concentration of the epitaxial semiconductor layer 32. Therefore, in the photodetection element 1, when a voltage is applied, the intensity of an electric field generated in the epitaxial semiconductor region 311 increases. The intensity of the electric field generated in the epitaxial semiconductor region 311 affects the avalanche probability, which indicates the probability that generated carriers cause avalanche multiplication. Specifically, when the intensity of the electric field generated in the epitaxial semiconductor region 311 increases, the avalanche probability also increases. Therefore, the photodetection element 1 increases the avalanche probability.

Furthermore, in the configuration in which the relationship between the thickness T1 and the thickness T2 satisfies the above-described relationship, secondary photons of carriers multiplied in a certain avalanche photodiode APD tend not to enter an adjacent avalanche photodiode APD. In addition, in the photodetection element 1, since the semiconductor substrate 3 is provided with the trench 40 that surrounds the semiconductor region 312 when viewed from the Z-axis direction, the secondary photons are controlled from entering the adjacent avalanche photodiode APD.

From the above, the photodetection element 1 improves the detection efficiency and controls crosstalk.

In the photodetection element 1, the trench 40 opens at the surface 3b and reaches at least the epitaxial semiconductor layer 32.

In the photodetection element 1, the secondary photons of carriers multiplied in a certain avalanche photodiode APD are further controlled from entering the adjacent avalanche photodiode APD. That is, the photodetection element 1 further controls crosstalk.

In the photodetection element 1, the trench 40 does not reach the semiconductor layer 33.

In the photodetection element 1, the configuration of the photodetection element 1 can be simplified.

In the photodetection element 1, the sum of the thickness T1 and the thickness T2 is twice or more the sum of the thickness T5 and the thickness T4.

In the configuration in which the relationship between the thickness T1 and the thickness T2 satisfies the above-described relationship, the length of the optical path in the photodetection element 1 can be further increased compared to a configuration in which the semiconductor substrate 3 includes a single epitaxial semiconductor layer. Therefore, the photodetection element 1 further improves the detection efficiency and further controls crosstalk.

The photodetection element 1 further includes the plurality of light-reflecting layers 16 provided on the surface 3b.

Each of the plurality of light-reflecting layers 16 is disposed on the surface 3b to oppose the corresponding semiconductor region 312 among the plurality of semiconductor regions 312 and reflects light incident from the surface 3a. In the photodetection element 1, the length of the optical path in the photodetection element can be further increased. Therefore, the photodetection element 1 further improves the detection efficiency and further controls crosstalk.

In the method for manufacturing the photodetection element 1, the epitaxial semiconductor layer 31 and the epitaxial semiconductor layer 32 are formed such that the epitaxial semiconductor layer 32 has the thickness T2 greater than the thickness T1 of the epitaxial semiconductor layer 31, and the sum of the thickness T1 and the thickness T2 is 20 μm or more and 50 μm or less. Therefore, in the photodetection element 1 manufactured by the present manufacturing method, the length of the optical path in the photodetection element 1 can be increased compared to a configuration in which the semiconductor substrate 3 includes a single epitaxial semiconductor layer. That is, the photodetection element 1 manufactured by the present manufacturing method improves the quantum efficiency.

In the present manufacturing method, the epitaxial semiconductor layer 31 is formed to have an impurity concentration higher than the impurity concentration of the epitaxial semiconductor layer 32. That is, the epitaxial semiconductor region 311 in the epitaxial semiconductor layer 31 has an impurity concentration higher than the impurity concentration of the epitaxial semiconductor layer 32. Therefore, in the photodetection element 1 manufactured by the present manufacturing method, when a voltage is applied, the intensity of the electric field generated in the epitaxial semiconductor region 311 increases. That is, the photodetection element 1 manufactured by the present manufacturing method increases the avalanche probability.

Furthermore, when the epitaxial semiconductor layer 31 and the epitaxial semiconductor layer 32 are formed such that the relationship between the thickness T1 and the thickness T2 satisfies the above-described relationship, secondary photons of carriers multiplied in a certain avalanche photodiode APD tend not to enter an adjacent avalanche photodiode APD. In addition, in the present manufacturing method, since the trench 40 that surrounds the semiconductor region 312 when viewed from the Z-axis direction is provided in the semiconductor substrate 3, in the photodetection element 1 manufactured by the manufacturing method, the secondary photons are controlled from entering the adjacent avalanche photodiode APD.

From the above, the photodetection element 1 manufactured by the present manufacturing method improves the detection efficiency and controls crosstalk.

### Second Embodiment

### Configuration of Photodetection Element

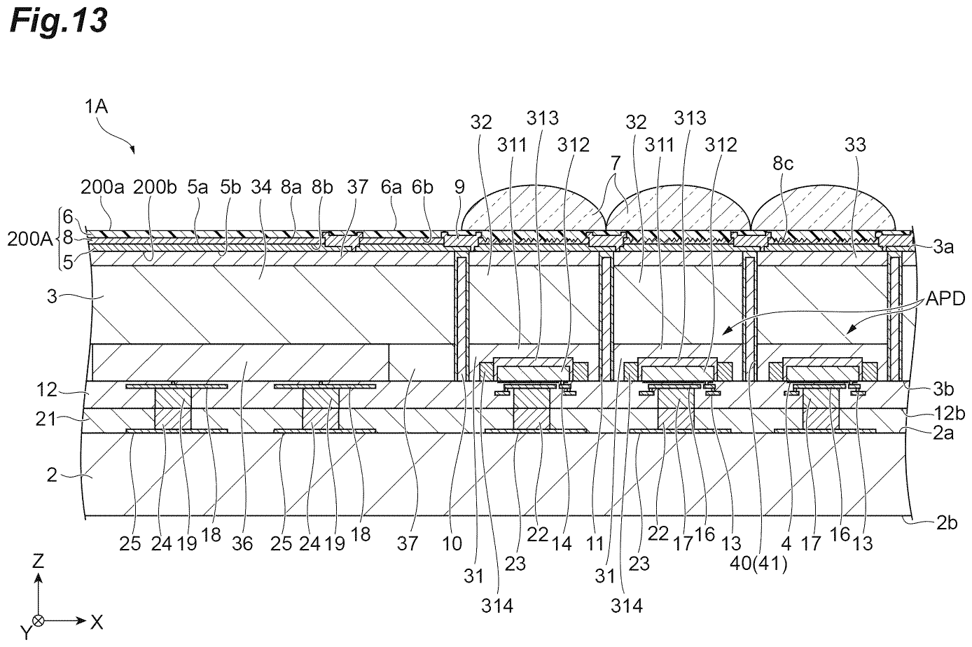

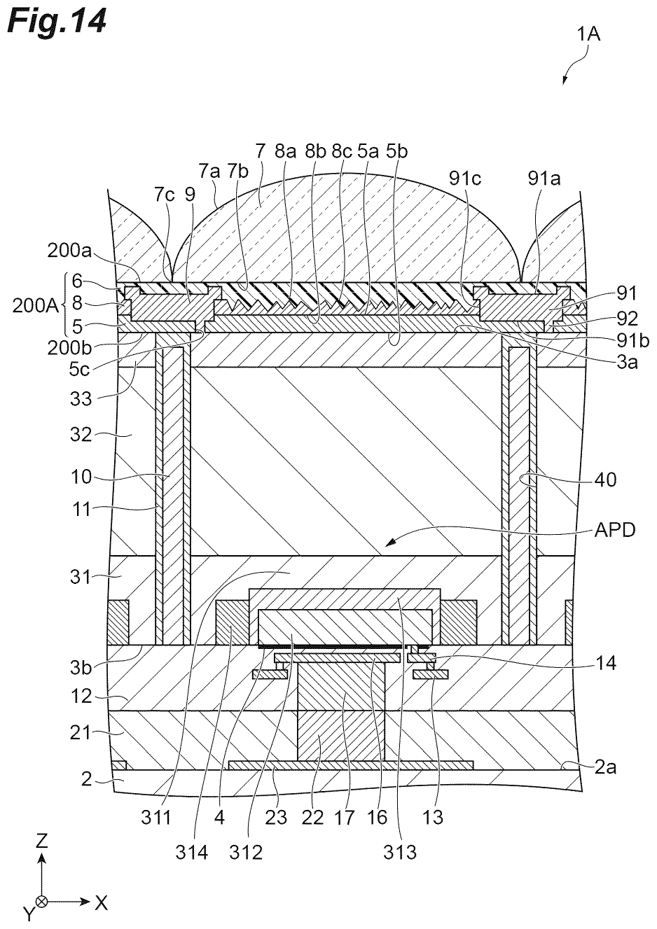

Next, a configuration of a photodetection element 1A according to a second embodiment will be described with reference to FIGS. 13 and 14. FIG. 13 is a plan view schematically illustrating a photodetection element according to the second embodiment. FIG. 14 is a partial cross-sectional view illustrating the photodetection element illustrated in FIG. 13. The photodetection element 1A according to the second embodiment is similar to or the same as the photodetection element 1 according to the first embodiment described above, but the photodetection element 1A differs from the photodetection element 1 with respect to the configuration of the insulating layer 12, the configuration of the trench 40, and the configuration of the layered structure 200. Hereinafter, differences between the first embodiment and the second embodiment described above will be mainly described.

In the photodetection element 1A, the plurality of wiring layers 15 are not formed in the insulating layer 12. That is, the photodetection element 1A does not include the plurality of wiring layers 15. Therefore, in the present embodiment, the other end of the quenching element 13 is electrically connected to the light-reflecting layer 16 without an intervening wiring layer 15. In the present embodiment, for example, the quenching element 13 may be located inside the corresponding frame portion 41 when viewed from the Z-axis direction. When viewed from the Z-axis direction, an outer edge of the quenching element 13 may extend along an inner edge 41a of the frame portion 41.

In the photodetection element 1A, the trench 40 opens at the surface 3b and reaches the semiconductor layer 33. In the photodetection element 1A, the trench 40 penetrates the semiconductor layer 33 and also opens at the surface 3a. The trench 40 penetrates the epitaxial semiconductor layer 31, the epitaxial semiconductor layer 32, and the semiconductor layer 33. That is, in the photodetection element 1A, the trench 40 penetrates the semiconductor substrate 3.

The photodetection element 1A includes a layered structure 200A instead of the layered structure 200. The layered structure 200A includes the insulating layer 5, the spacer layer 6, and a semiconductor layer 8. The semiconductor layer 8 is formed on the surface 3a of the semiconductor substrate 3 via the insulating layer 5. The semiconductor layer 8 is formed directly on the insulating layer 5. The semiconductor layer 8 is in contact with the insulating layer 5. The semiconductor layer 8 is formed to cover the insulating layer 5. The semiconductor layer 8 is a semiconductor layer into which impurities are not implanted. As illustrated in FIG. 13, the semiconductor layer 8 has a main surface 8a and a main surface 8b. The main surface 8a is a surface on a side opposite to the insulating layer 5 in the semiconductor layer 8, and the main surface 8b is a surface on a side closer to the insulating layer 5 in the semiconductor layer 8. That is, the main surface 8a is located on a side opposite to the main surface 8b in the Z-axis direction. The thickness of the semiconductor layer 8 may be, for example, about several μm (in this example, 2 to 3 μm).

A texture structure 8c having an uneven shape is formed on a surface of the semiconductor layer 8. The texture structure 8c is formed on the main surface 8a of the semiconductor layer 8. In one example, the texture structure 8c has an irregular (non-uniform shape) uneven shape. In another example, the texture structure 8c may have a regular (uniform shape) uneven shape. The texture structure 8c is formed in a region of the main surface 8a that overlaps the epitaxial semiconductor layer 31 and the epitaxial semiconductor layer 32 in the Z-axis direction. That is, the texture structure 8c overlaps the plurality of avalanche photodiodes APD in the Z-axis direction. In this example, the texture structure 8c is not formed in a region of the main surface 8a that overlaps the semiconductor layer 34 in the Z-axis direction. In the main surface 8a, a region where the texture structure 8c is formed is rougher (has a larger surface roughness) and is less smooth than a region where the texture structure 8c is not formed.

In the photodetection element 1A, the spacer layer 6 is formed above the surface 3a of the semiconductor substrate 3, with the insulating layer 5 and the semiconductor layer 8 interposed therebetween. The spacer layer 6 is formed above the insulating layer 5, with the semiconductor layer 8 interposed therebetween. The spacer layer 6 is formed directly on the semiconductor layer 8. The spacer layer 6 is in contact with the main surface 8a of the semiconductor layer 8. The spacer layer 6 is formed to cover the texture structure 8c formed on the semiconductor layer 8. The spacer layer 6 fills concave portions of the texture structure 8c (uneven shape).

The photodetection element 1A further includes a metal wiring 9. The metal wiring 9 is disposed on the surface 3a of the semiconductor substrate 3. The metal wiring 9 extends along the trench 40 when viewed from the Z-axis direction. That is, the metal wiring 9 is formed on the surface 3a to extend along the trench 40. The metal wiring 9 extends in a mesh shape when viewed from the Z-axis direction. At least a part of the metal wiring 9 is located inside the layered structure 200A. In the examples illustrated in FIGS. 13 and 14, all of the metal wiring 9 is located inside the layered structure 200A. That is, the metal wiring 9 is located inside the insulating layer 5, the semiconductor layer 8, and the spacer layer 6. The metal wiring 9 is formed of a metal material. The metal wiring 9 has a body portion 91 extending along the trench 40 and a plurality of contact portions 92 integrally formed with the body portion 91.

The body portion 91 is a wiring layer having a thickness in the Z-axis direction. The body portion 91 has a surface 91a, a surface 91b, and a side surface 91c. The surface 91a is a surface of the body portion 91 on a side opposite to the surface 3a of the semiconductor substrate 3. In the Z-axis direction, the surface 91a is located farther from the surface 3a than the main surface 5a of the insulating layer 5. The surface 91a protrudes from the insulating layer 5. That is, the surface 91a is exposed from the insulating layer 5. In this example, the surface 91a is located inside the spacer layer 6 and is in contact with the spacer layer 6.

The surface 91b is a surface of the body portion 91 on a side closer to the surface 3a. The surface 91b is located inside the insulating layer 5 and is in contact with the insulating layer 5. A part of the insulating layer 5 is located between the surface 91b and the trench 40. The side surface 91c is a surface connecting the surface 91a and the surface 91b. The side surface 91c is in contact with the insulating layer 5, the semiconductor layer 8, and the spacer layer 6.

The plurality of contact portions 92 are formed on the surface 91b of the body portion 91. Each contact portion 92 is located in a corresponding opening 5c formed in the insulating layer 5. The contact portion 92 is formed in a columnar shape. Each contact portion 92 is in contact with the corresponding semiconductor layer 33 and the semiconductor layer 37. The metal wiring 9 electrically connects the semiconductor layers 33 to each other and electrically connects the plurality of semiconductor layers 33 to the semiconductor layer 37.

When viewed from the Z-axis direction, the metal wiring 9 is formed to cover the entire trench 40. The metal wiring 9 overlaps the trench 40 in the Z-axis direction. When viewed from the Z-axis direction, each of the plurality of avalanche photodiodes APD is surrounded by the metal wiring 9.

### Method for Manufacturing Photodetection Element

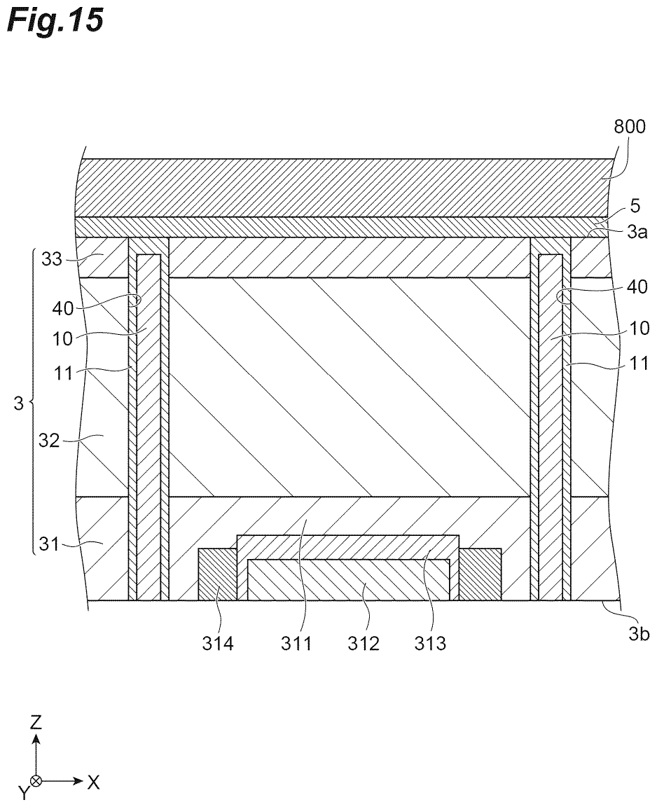

Next, a method for manufacturing the photodetection element 1A will be described with reference to FIGS. 15 to 21. FIGS. 15 to 21 are diagrams for explaining the method for manufacturing the photodetection element illustrated in FIG. 13. Also in the present manufacturing method, the semiconductor substrate 3 is first prepared. In the present manufacturing method, for example, the semiconductor substrate 3 is prepared as follows. First, the insulating layer 5 is formed on the semiconductor layer 800. In the present manufacturing method, the semiconductor layer 800 is a semiconductor layer that becomes the semiconductor layer 8 through the manufacturing process of the photodetection element 1A. Next, the semiconductor layer 33, the epitaxial semiconductor layer 32, and the epitaxial semiconductor layer 31 are formed on the insulating layer 5 in this order. In the present manufacturing method, the semiconductor layer 33 is formed on the insulating layer 5, for example, by epitaxial growth. Next, the epitaxial semiconductor region 311, the plurality of semiconductor regions 312, the plurality of semiconductor regions 313, and the plurality of semiconductor regions 314 are formed in the epitaxial semiconductor layer 31. The epitaxial semiconductor layer 31, the epitaxial semiconductor layer 32, the epitaxial semiconductor region 311, the plurality of semiconductor regions 312, the plurality of semiconductor regions 313, and the plurality of semiconductor regions 314 are formed, for example, in the same manner as in the first embodiment described above.

After the epitaxial semiconductor region 311 and the semiconductor region 312 are formed, the trench 40 is provided. In the present manufacturing method, as illustrated in FIG. 15, the trench 40 is provided from the surface 3b to the surface 3a in a direction from the surface 3b toward the surface 3a. That is, in the present manufacturing method, the trench 40 penetrating the semiconductor substrate 3 is provided. After the trench 40 is provided, the metal portion 10 and the insulating film 11 are formed inside the trench 40.

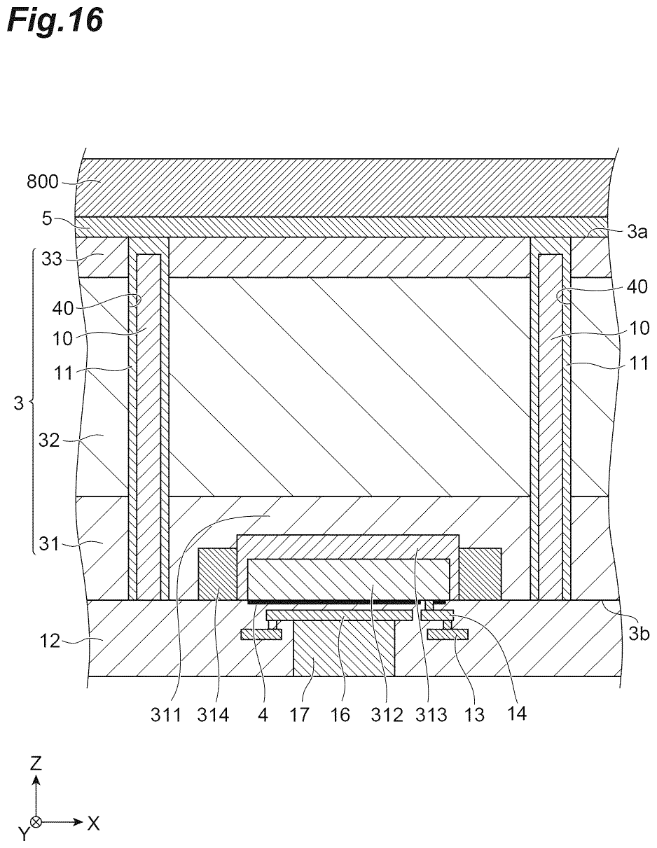

Next, as illustrated in FIG. 16, the insulating layer 12 is formed on the surface 3b of the semiconductor substrate 3. In the present manufacturing method, the insulating layer 12 having the plurality of quenching elements 13, the plurality of wiring layers 14, the plurality of light-reflecting layers 16, and the plurality of connection conductors 17 formed therein is formed on the surface 3b. The insulating layer 12 is formed, for example, in the same manner as in the first embodiment described above.

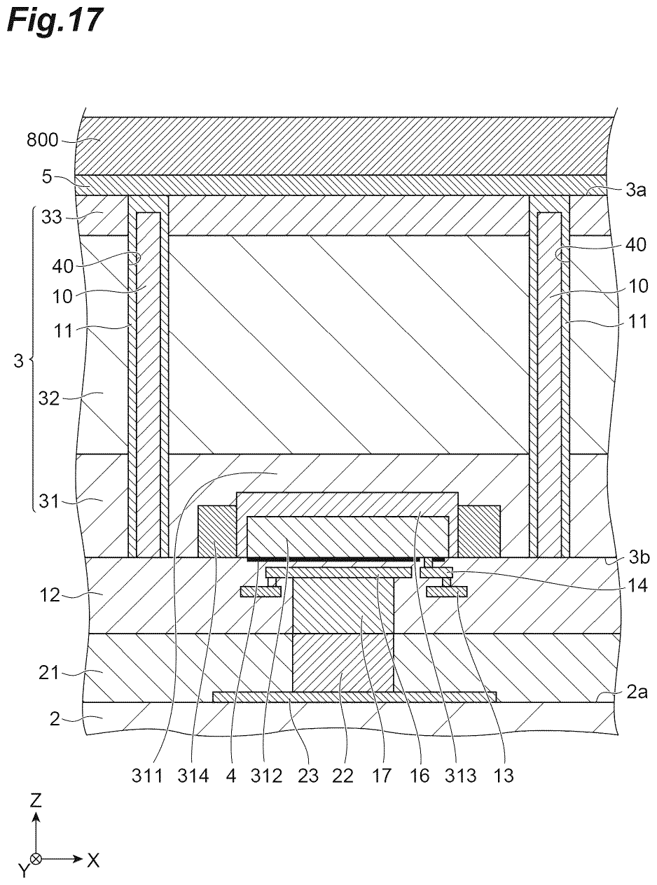

Next, as illustrated in FIG. 17, a stacked body of the substrate 2 and the insulating layer 21 is prepared, and the insulating layer 12 and the insulating layer 21 are bonded to each other. The bonding of the insulating layer 12 and the insulating layer 21 is performed, for example, in the same manner as in the first embodiment described above.

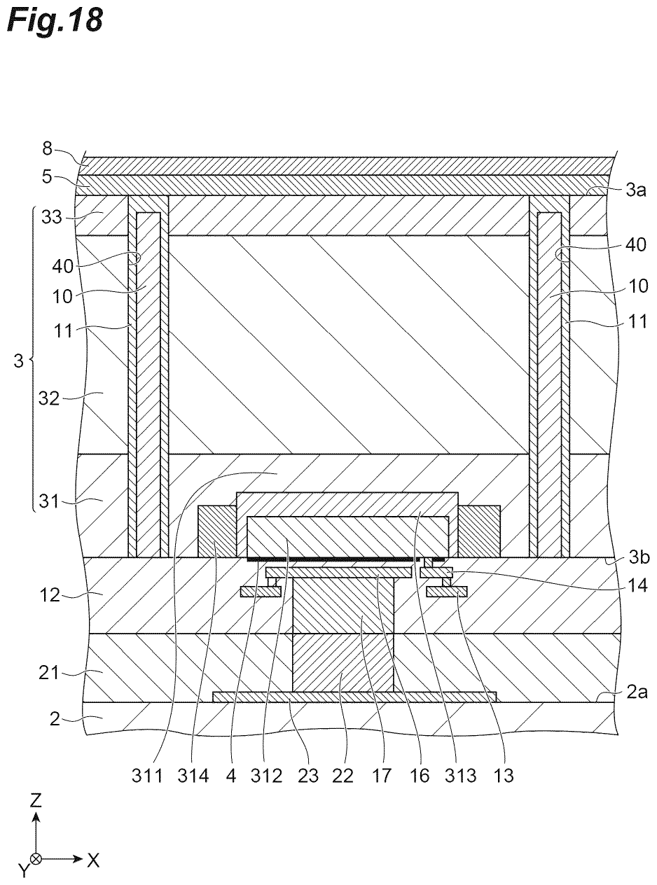

Next, as illustrated in FIG. 18, the semiconductor layer 8 is formed. In the present manufacturing method, the semiconductor layer 8 is formed by polishing and thinning the semiconductor layer 800. Specifically, the semiconductor layer 800 is polished until the thickness of the semiconductor layer 800 becomes, for example, about several tens of μm. In this example, the semiconductor layer 800 is polished such that the thickness of the semiconductor layer 800 after thinning becomes 10 μm or less (in this example, 2 to 3 μm). The thinning of the semiconductor layer 800 may be performed by chemical mechanical polishing or may be performed by etching.

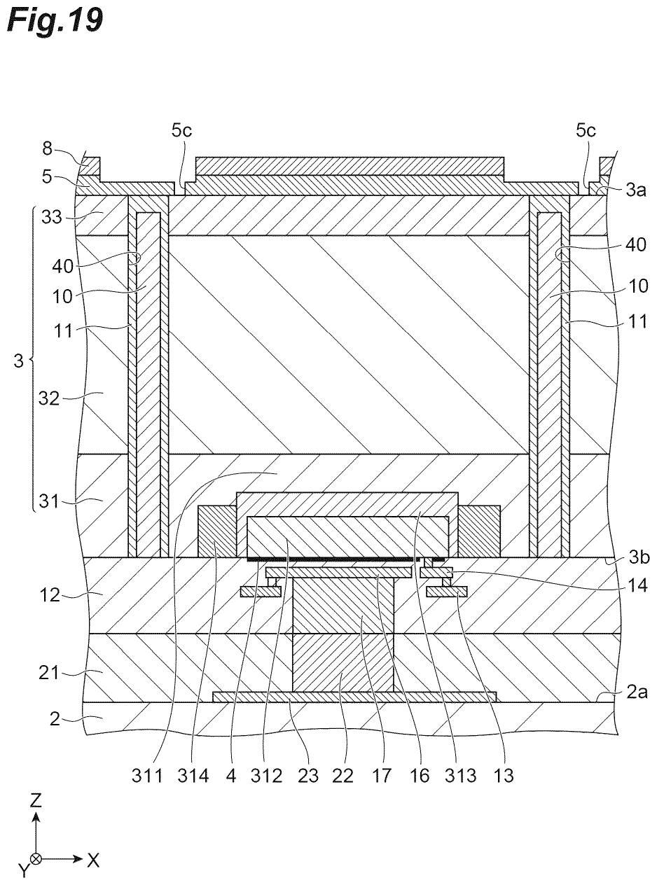

Next, as illustrated in FIG. 19, the opening 5c for disposing the metal wiring 9 is formed. In the present manufacturing method, the opening 5c is formed by removing a part of the insulating layer 5 and a part of the semiconductor layer 8. The removal of the insulating layer 5 and the semiconductor layer 8 is performed, for example, by etching.

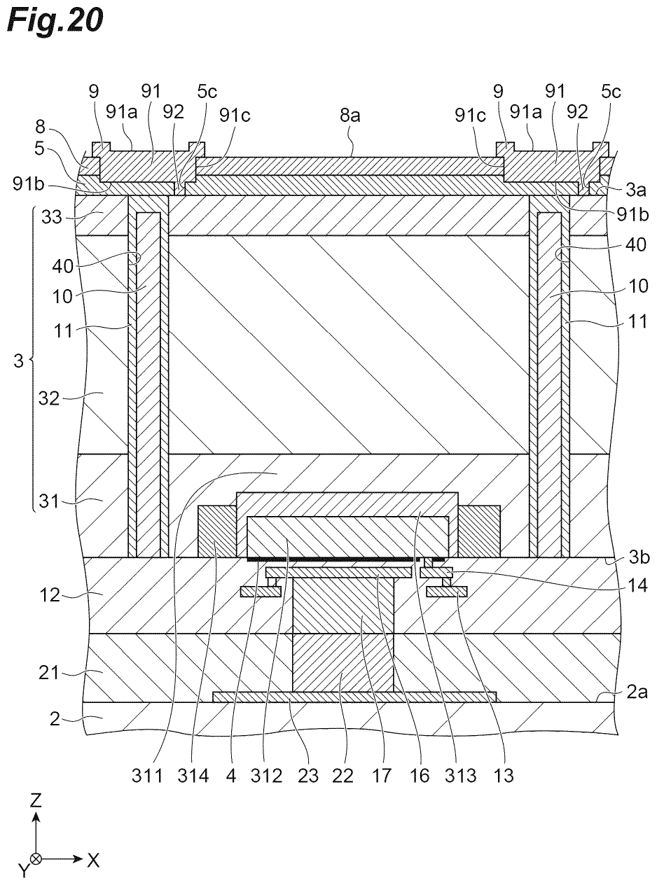

Next, as illustrated in FIG. 20, the metal wiring 9 is formed. In the present manufacturing method, the metal wiring 9 is formed in a portion where the insulating layer 5 and the semiconductor layer 8 are removed. In the present manufacturing method, the metal wiring 9 is formed such that the contact portion 92 is located in the opening 5c.

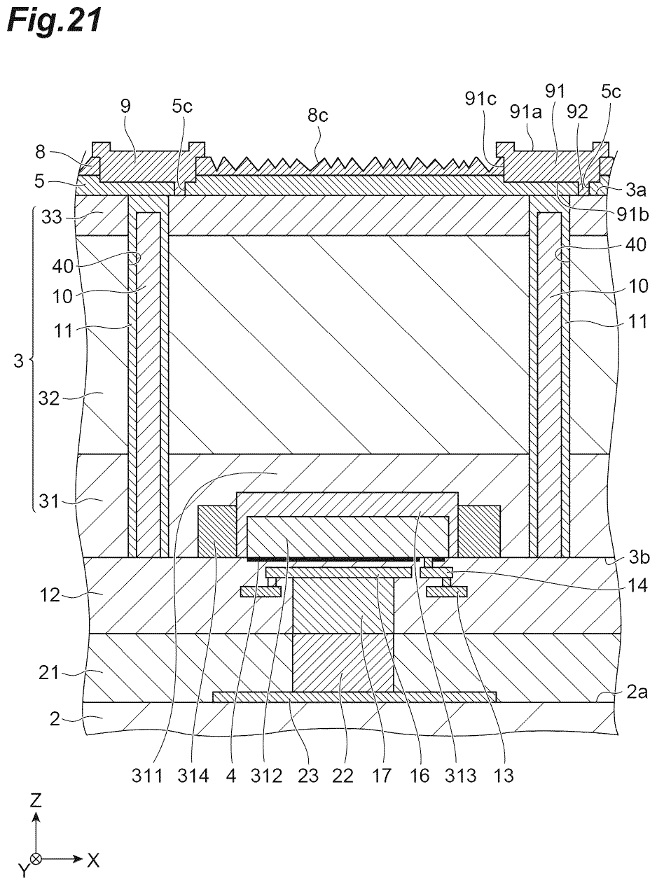

Next, as illustrated in FIG. 21, the texture structure 8c having an uneven shape is formed on the surface of the semiconductor layer 8. The texture structure 8c is formed on the main surface 8a on a side opposite to the insulating layer 5 in the semiconductor layer 8. For example, in a configuration in which the texture structure 8c has an irregular uneven shape, the texture structure 8c is formed by etching the main surface 8a. The etching may be wet etching using a liquid etchant. Alternatively, in a configuration in which the texture structure 8c has a regular uneven shape, the texture structure 8c may be formed by removing a part of the semiconductor layer 8 using a photolithography technique using a mask.

Next, as illustrated in FIGS. 13 and 14, the plurality of lenses 7 are provided on the surface 3a. In the present manufacturing method, for example, the plurality of lenses 7 are provided as follows. First, the spacer layer 6 is formed to cover the texture structure 8c and the metal wiring 9. Next, the plurality of lenses 7 are provided on the spacer layer 6. As a result, the plurality of lenses 7 are provided on the surface 3a. The plurality of lenses 7 are provided on the surface 3a, for example, in the same manner as in the first embodiment described above. Through the above processes, the photodetection element 1A is manufactured.

### Third Embodiment

### Configuration of Photodetection Element

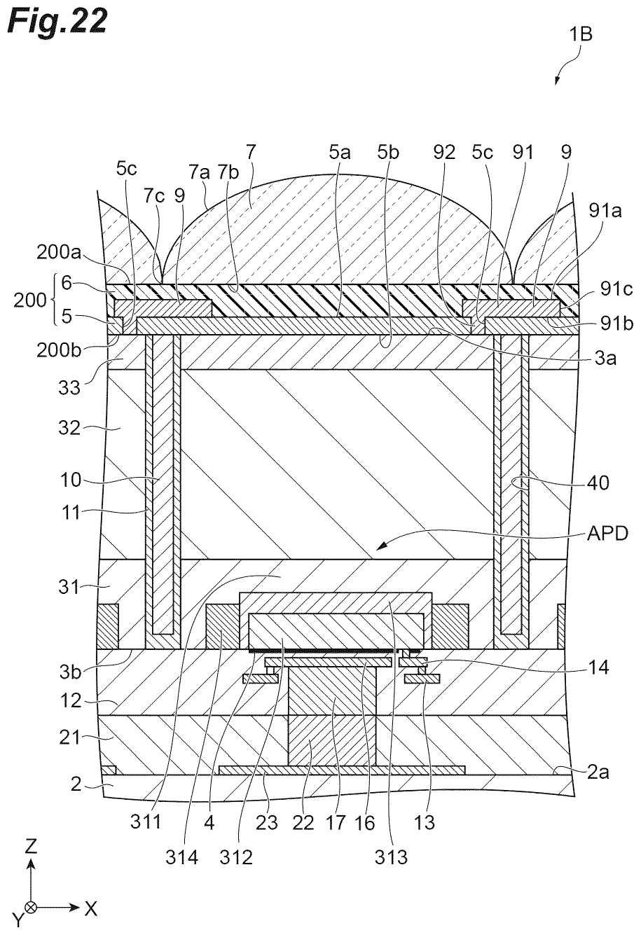

Next, a configuration of a photodetection element 1B according to a third embodiment will be described with reference to FIG. 22. FIG. 22 is a partial cross-sectional view illustrating a photodetection element according to the third embodiment. The photodetection element 1B according to the third embodiment is similar to or the same as the photodetection element 1 according to the first embodiment described above, but the photodetection element 1B differs from the photodetection element 1 with respect to the configuration of the trench 40 and the configuration of the layered structure 200. Hereinafter, differences between the first embodiment and the third embodiment described above will be mainly described.

In the photodetection element 1B, the trench 40 opens at the surface 3a and reaches at least the epitaxial semiconductor layer 31. That is, in the photodetection element 1B, the trench 40 penetrates the semiconductor layer 33 and the epitaxial semiconductor layer 32. In the example illustrated in FIG. 22, the trench 40 also penetrates the epitaxial semiconductor layer 31. That is, the trench 40 also opens at the surface 3b.

The photodetection element 1B further includes the metal wiring 9. The metal wiring 9 extends along the trench 40 when viewed from the Z-axis direction. The metal wiring 9 is located inside the insulating layer 5 and the spacer layer 6. The body portion 91 of the metal wiring 9 is located inside the insulating layer 5 and the spacer layer 6, and the contact portion 92 of the metal wiring 9 is located inside the insulating layer 5. Therefore, in the photodetection element 1B, the spacer layer 6 is formed on the insulating layer 5 to cover the metal wiring 9. The spacer layer 6 covers the main surface 5a of the insulating layer 5, and the surface 91a and the side surface 91c of the metal wiring 9. The body portion 91 may be located inside the spacer layer 6 without being located inside the insulating layer 5. That is, the body portion 91 may be formed on the main surface 5a of the insulating layer 5 such that the entire body portion 91 is exposed from the insulating layer 5.

In the photodetection element 1B, the plurality of wiring layers 15 are not formed in the insulating layer 12. That is, the photodetection element 1B does not include the plurality of wiring layers 15. Therefore, in the present embodiment, the other end of the quenching element 13 is electrically connected to the light-reflecting layer 16 without the wiring layer 15.

In the photodetection element 1B, the trench 40 reaches the epitaxial semiconductor layer 31.

The photodetection element 1B tends to increase the aperture ratio in the avalanche photodiode APD. Here, the detection efficiency is affected not only by the quantum efficiency and the avalanche probability but also by the aperture ratio in the avalanche photodiode APD. For example, when the aperture ratio in the avalanche photodiode APD increases, the detection efficiency increases. Therefore, the photodetection element 1B can further improve the detection efficiency.

### Method for Manufacturing Photodetection Element

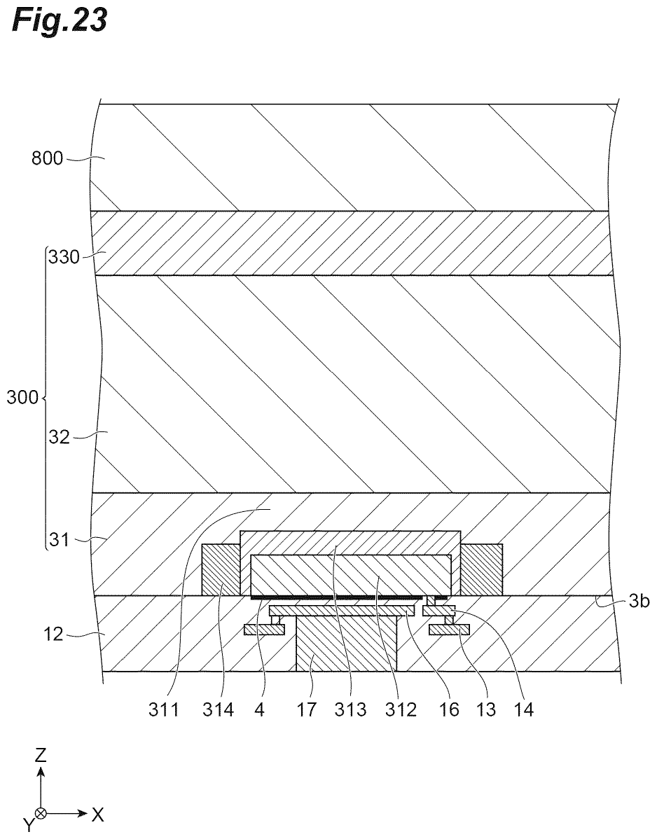

Next, a method for manufacturing the photodetection element 1B will be described with reference to FIGS. 23 to 28. FIGS. 23 to 28 are diagrams for explaining the method for manufacturing the photodetection element illustrated in FIG. 22. In the present manufacturing method, first, the semiconductor substrate 3 is prepared. In the present manufacturing method, for example, the semiconductor substrate 3 is prepared as follows. First, a stacked body including the semiconductor substrate 300 and the semiconductor layer 800 is prepared. The stacked body including the semiconductor substrate 300 and the semiconductor layer 800 is prepared, for example, in the same manner as in the first embodiment described above.

Next, as illustrated in FIG. 23, the insulating layer 12 is formed on the surface 3b of the semiconductor substrate 300. The formation of the insulating layer 12 is performed, for example, in the same manner as in the first embodiment and the second embodiment described above. Also in the present manufacturing method, after the insulating layer 12 is formed, a planarization process may be performed on a surface of the insulating layer 12 on a side opposite to the semiconductor substrate 300.

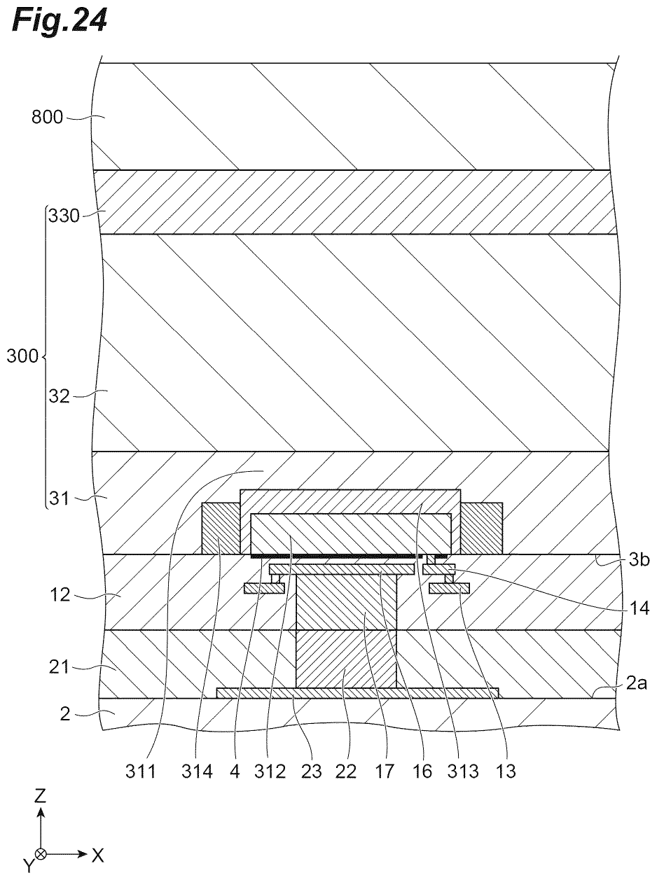

Next, as illustrated in FIG. 24, a stacked body of the substrate 2 and the insulating layer 21 is prepared, and the insulating layer 12 and the insulating layer 21 are bonded to each other. The bonding of the insulating layer 12 and the insulating layer 21 is performed, for example, in the same manner as in the first embodiment and the second embodiment described above.

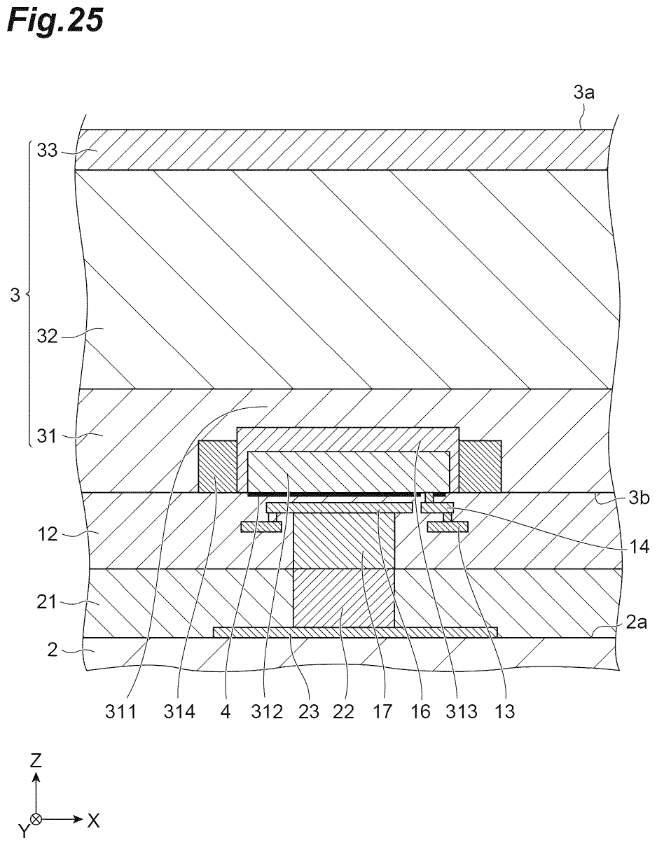

Next, as illustrated in FIG. 25, the semiconductor layer 800 is removed. The removal of the semiconductor layer 800 is performed, for example, in the same manner as in the first embodiment described above. Also in the present manufacturing method, a part of the semiconductor layer 330 is removed together with the semiconductor layer 800. That is, in the present manufacturing method, the semiconductor layer 330 is thinned. In the present manufacturing method, the thinned semiconductor layer 330 becomes the semiconductor layer 33. In the present manufacturing method, the semiconductor substrate 3 is thus prepared.

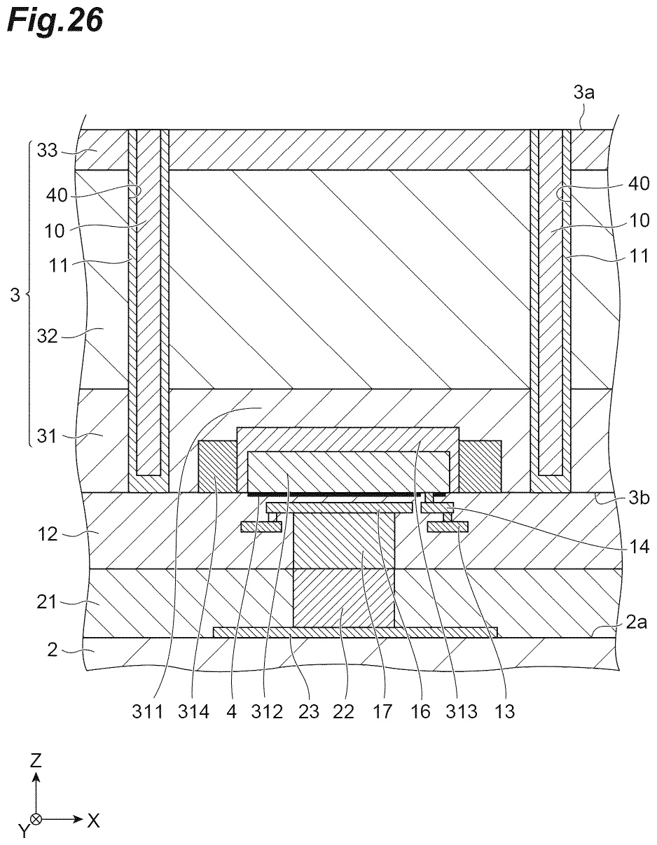

Next, as illustrated in FIG. 26, the trench 40 is provided. Also in the present manufacturing method, the trench 40 is provided to surround the semiconductor region 312 when viewed from the Z-axis direction. The trench 40 is provided in the semiconductor substrate 300, for example, by etching. In the present manufacturing method, the trench 40 is provided from the surface 3a toward the surface 3b. In the present manufacturing method, as illustrated in FIG. 26, the trench 40 is provided from the surface 3a to the surface 3b in a direction from the surface 3a toward the surface 3b. That is, in the present manufacturing method, the trench 40 penetrating the semiconductor substrate 3 is provided. After the trench 40 is provided, the metal portion 10 and the insulating film 11 are formed inside the trench 40.

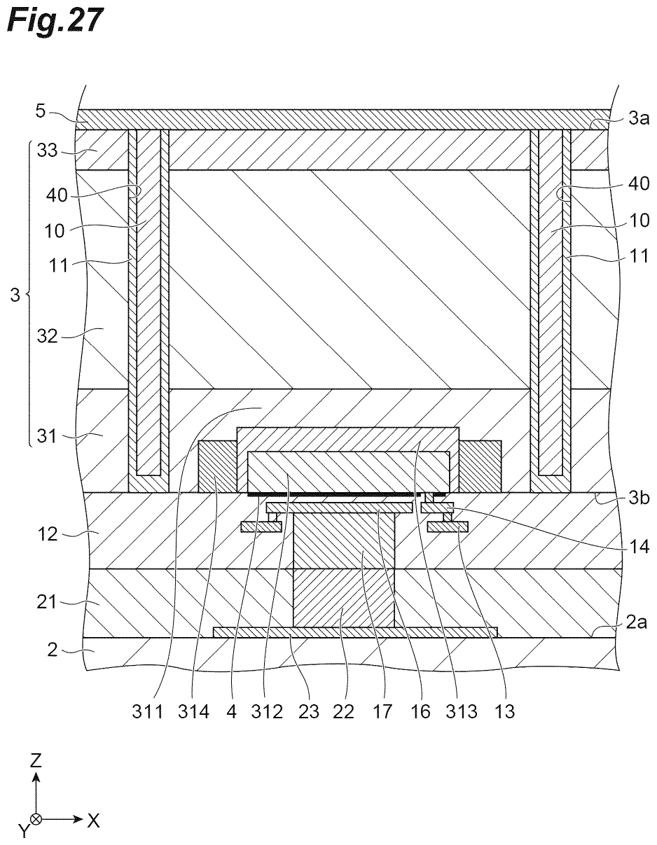

Next, as illustrated in FIG. 27, the insulating layer 5 is formed on the surface 3a of the semiconductor substrate 3. In one example, a SiN film is formed as the insulating layer 5 on the surface 3a. In this example, the SiN film also functions as an anti-reflection film.

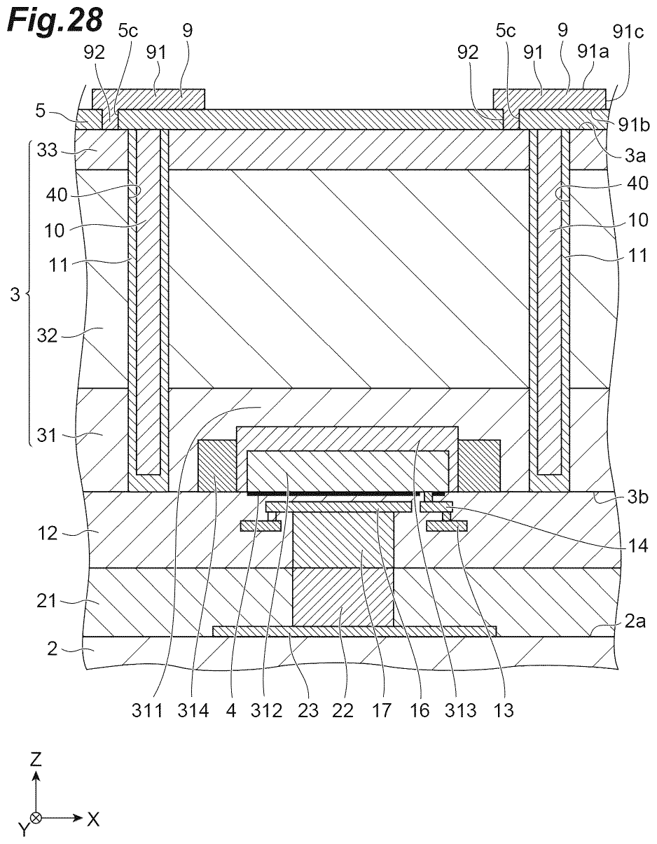

Next, as illustrated in FIG. 28, the opening 5c for disposing the metal wiring 9 is formed in the insulating layer 5, and the metal wiring 9 is formed in the opening 5c. The formation of the opening 5c is performed, for example, in the same manner as in the second embodiment described above. In the present manufacturing method, the metal wiring 9 is formed such that the contact portion 92 is located in the opening 5c.

Next, as illustrated in FIG. 22, the plurality of lenses 7 are provided on the surface 3a. In the present manufacturing method, for example, the plurality of lenses 7 are provided as follows. First, the spacer layer 6 is formed to cover the insulating layer 5 and the metal wiring 9. Next, the plurality of lenses 7 are provided on the spacer layer 6. As a result, the plurality of lenses 7 are provided on the surface 3a. The plurality of lenses 7 are provided on the surface 3a, for example, in the same manner as in the first embodiment and the second embodiment described above. Through the above processes, the photodetection element 1B is manufactured.

### Modifications

Although the embodiments of the present disclosure have been described above, the present disclosure is not necessarily limited to the above-described embodiments, and various modifications are possible without departing from the gist thereof.

In the first to third embodiments described above, the photodetection elements 1, 1A, and 1B may be configured as a SiPM (Silicon Photomultiplier). An example of the SiPM includes MPPC (Multi-Pixel Photon Counter) (registered trademark). In the photodetection element 1 configured as a SiPM, a plurality of cell units each including an avalanche photodiode APD and a quenching element 13 connected in series are connected in parallel to each other to constitute one channel.

In the first to third embodiments described above, in the epitaxial semiconductor layer 31, the epitaxial semiconductor region 311, the semiconductor region 314, and the semiconductor region 313 are located between the trench 40 and the semiconductor region 312. However, the configuration of the epitaxial semiconductor region 311, the semiconductor region 312, the semiconductor region 313, and the semiconductor region 314 in the epitaxial semiconductor layer 31 is not limited to the above-described configuration. For example, in the epitaxial semiconductor layer 31, the semiconductor region 312 may be formed across the entire space between adjacent trenches 40. That is, the surface 3b may be constituted only by the semiconductor region 312. In this case, the epitaxial semiconductor layer 31 may not include the semiconductor region 314. In addition, the epitaxial semiconductor region 311 may be located inside the corresponding semiconductor region 312 when viewed from the Z-axis direction.

In one example, a texture structure may be formed in the photodetection element 1. In a configuration in which a texture structure is formed in the photodetection element 1, in one example, the texture structure is formed on the semiconductor layer 33. In this example, the texture structure is formed on a surface of the semiconductor layer 33 located on a side opposite to the epitaxial semiconductor layer 32. The formation of the texture structure on the surface of the semiconductor layer 33 is performed, for example, in the same manner as the formation of the texture structure 8c in the second embodiment described above. Furthermore, in this example, the layered structure 200 may include only the spacer layer 6. The spacer layer 6 is formed to cover the texture structure formed on the semiconductor layer 33. The spacer layer 6 fills concave portions of the texture structure formed on the semiconductor layer 33.

In one example, the photodetection element 1 in which the texture structure is formed on the semiconductor layer 33 may be manufactured as follows. First, the semiconductor substrate 3, the insulating layer 12, the insulating layer 21, and the substrate 2 illustrated in FIG. 12 are manufactured through the same processes as in the first embodiment described above. Next, the semiconductor layer 800 is removed, and the texture structure is formed on the surface of the semiconductor layer 33. Next, after the spacer layer 6 is formed to cover the semiconductor layer 33 on which the texture structure is formed, the plurality of lenses 7 are provided on the surface 3a in the same manner as in the first embodiment described above.

In another example, the photodetection element 1 in which the texture structure is formed on the semiconductor layer 33 may be manufactured as follows. First, a stacked body including the semiconductor substrate 300, an insulating layer, and the semiconductor layer 800 is prepared. The insulating layer is, for example, a BOX layer (buried oxide layer) formed of SiO₂. In this example, the insulating layer is stacked on the semiconductor layer 800, and the semiconductor layer 330 is stacked on the insulating layer. Next, the semiconductor layer 800 is removed through the same processes as in the first embodiment described above. In this example, since the insulating layer is disposed between the semiconductor substrate 300 and the semiconductor layer 800, the semiconductor layer 330 is not thinned by the removal of the semiconductor layer 800. Next, the insulating layer is removed, and the texture structure is formed on the semiconductor layer 330. In this example, the semiconductor layer 330 on which the texture structure is formed on the surface thereof becomes the semiconductor layer 33. Next, after the spacer layer 6 is formed to cover the texture structure, the plurality of lenses 7 are provided on the surface 3a in the same manner as in the first embodiment described above.

In one example, in the method for manufacturing the photodetection element 1, a stacked body including the semiconductor substrate 300, an insulating layer, and the semiconductor layer 800 may be prepared. The insulating layer is, for example, a BOX layer (buried oxide layer) formed of SiO₂. In this example, the insulating layer is stacked on the semiconductor layer 800, and the semiconductor layer 330 is stacked on the insulating layer. In this example, after the stacked body including the semiconductor substrate 300, the insulating layer, and the semiconductor layer 800 is prepared, the epitaxial semiconductor region 311, the plurality of semiconductor regions 312, the plurality of semiconductor regions 313, and the plurality of semiconductor regions 314 are formed in the epitaxial semiconductor layer 31. The epitaxial semiconductor layer 31, the epitaxial semiconductor layer 32, the epitaxial semiconductor region 311, the plurality of semiconductor regions 312, the plurality of semiconductor regions 313, and the plurality of semiconductor regions 314 are formed, for example, in the same manner as in the first embodiment described above.

Next, the trench 40 is provided in the same manner as in the first embodiment described above. Next, the insulating layer 12 is formed on the surface 3b, and the insulating layer 12 and the insulating layer 21 are bonded to each other in the same manner as in the first embodiment described above. Next, the semiconductor layer 800 is removed in the same manner as in the first embodiment described above. As a result, the insulating layer located between the semiconductor substrate 300 and the semiconductor layer 800 is exposed. Next, the insulating layer is removed, and the insulating layer 5 is formed to cover the semiconductor layer 33. In one example, the insulating layer 5 may be a SiN film that also functions as an anti-reflection film. Next, after the spacer layer 6 is formed to cover the insulating layer 5, the plurality of lenses 7 are provided on the surface 3a in the same manner as in the first embodiment described above.

In one example, in the method for manufacturing the photodetection element 1, the semiconductor substrate 300 prepared may not include the semiconductor layer 330. When the semiconductor substrate 300 does not include the semiconductor layer 330, the photodetection element 1 may be manufactured, for example, as follows. First, a stacked body including the semiconductor substrate 300 and the semiconductor layer 800 is prepared. In this example, the semiconductor substrate 300 that does not include the semiconductor layer 330 and includes the epitaxial semiconductor layer 31 and the epitaxial semiconductor layer 32 is prepared. The epitaxial semiconductor layer 32 is formed on the semiconductor layer 800 by epitaxial growth, and the epitaxial semiconductor layer 31 is formed on the epitaxial semiconductor layer 32 by epitaxial growth. Next, the epitaxial semiconductor region 311, the plurality of semiconductor regions 312, the plurality of semiconductor regions 313, and the plurality of semiconductor regions 314 are formed in the epitaxial semiconductor layer 31. The epitaxial semiconductor layer 31, the epitaxial semiconductor layer 32, the epitaxial semiconductor region 311, the plurality of semiconductor regions 312, the plurality of semiconductor regions 313, and the plurality of semiconductor regions 314 are formed, for example, in the same manner as in the first embodiment described above.

Next, the trench 40 is provided in the same manner as in the first embodiment described above. Next, the insulating layer 12 is formed on the surface 3b, and the insulating layer 12 and the insulating layer 21 are bonded to each other in the same manner as in the first embodiment described above. Next, the semiconductor layer 800 is removed in the same manner as in the first embodiment described above. At this time, a part of the epitaxial semiconductor layer 32 may be removed together with the semiconductor layer 800. That is, the epitaxial semiconductor layer 32 may be thinned.

Next, the semiconductor layer 33 is formed to cover the epitaxial semiconductor layer 32. In one example, the semiconductor layer 33 is formed by implanting impurities into the epitaxial semiconductor layer 32. The impurities may be, for example, boron (B). Next, the insulating layer 5 is formed to cover the semiconductor layer 33. In one example, the insulating layer 5 may be a SiN film that also functions as an AR film. Next, after the spacer layer 6 is formed to cover the insulating layer 5, the plurality of lenses 7 are provided on the surface 3a in the same manner as in the first embodiment described above.

Alternatively, in the configuration in which the semiconductor substrate 300 does not include the semiconductor layer 330, the photodetection element 1 may be manufactured, for example, as follows. First, a stacked body including the semiconductor substrate 300, an insulating layer, and the semiconductor layer 800 is prepared. The insulating layer is, for example, a BOX layer (buried oxide layer) formed of SiO₂. In this example, the insulating layer is stacked on the semiconductor layer 800, and the epitaxial semiconductor layer 32 is stacked on the insulating layer.

The epitaxial semiconductor layer 32 is formed on the semiconductor layer 800 by epitaxial growth, and the epitaxial semiconductor layer 31 is formed on the epitaxial semiconductor layer 32 by epitaxial growth. Next, the epitaxial semiconductor region 311, the plurality of semiconductor regions 312, the plurality of semiconductor regions 313, and the plurality of semiconductor regions 314 are formed in the epitaxial semiconductor layer 31. The epitaxial semiconductor layer 31, the epitaxial semiconductor layer 32, the epitaxial semiconductor region 311, the plurality of semiconductor regions 312, the plurality of semiconductor regions 313, and the plurality of semiconductor regions 314 are formed, for example, in the same manner as in the first embodiment described above.

Next, the trench 40 is provided in the same manner as in the first embodiment described above. Next, the insulating layer 12 is formed on the surface 3b, and the insulating layer 12 and the insulating layer 21 are bonded to each other in the same manner as in the first embodiment described above. Next, the semiconductor layer 800 is removed in the same manner as in the first embodiment described above. As a result, the insulating layer located between the semiconductor substrate 300 and the semiconductor layer 800 is exposed. Next, the exposed insulating layer is removed, and the semiconductor layer 33 is formed to cover the epitaxial semiconductor layer 32. In one example, the semiconductor layer 33 is formed by implanting impurities into the epitaxial semiconductor layer 32. The impurities may be, for example, boron (B). Next, the insulating layer 5 is formed to cover the semiconductor layer 33. In one example, the insulating layer 5 may be a SiN film that also functions as an AR film. Next, after the spacer layer 6 is formed to cover the insulating layer 5, the plurality of lenses 7 are provided on the surface 3a in the same manner as in the first embodiment described above.

In one example, in the photodetection element 1A according to the second embodiment described above, the layered structure 200A may not include the semiconductor layer 8. In this example, the texture structure is not formed in the photodetection element 1A. When the layered structure 200A does not include the semiconductor layer 8, the metal wiring 9 is located inside the insulating layer 5 and the spacer layer 6. The body portion 91 of the metal wiring 9 is located inside the insulating layer 5 and the spacer layer 6, and the contact portion 92 of the metal wiring 9 is located inside the insulating layer 5.

In one example, the photodetection element 1A in which the layered structure 200A does not include the semiconductor layer 8 may be manufactured as follows. First, the semiconductor substrate 3, the insulating layer 5, the semiconductor layer 800, the insulating layer 12, the insulating layer 21, and the substrate 2 illustrated in FIG. 17 are manufactured through the same processes as in the second embodiment described above. Next, the semiconductor layer 800 is removed, and the insulating layer 5 is exposed. Next, the opening 5c for disposing the metal wiring 9 is formed in the insulating layer 5. The formation of the opening 5c is performed, for example, in the same manner as in the second embodiment described above. Next, the metal wiring 9 is formed such that the contact portion 92 is located in the opening 5c. Next, after the spacer layer 6 is formed to cover the insulating layer 5 and the metal wiring 9, the plurality of lenses 7 are provided on the surface 3a in the same manner as in the second embodiment described above.

In another example, in the photodetection element 1A according to the second embodiment described above, the layered structure 200A may include another insulating layer instead of the semiconductor layer 8. The insulating layer is located between the insulating layer 5 and the spacer layer 6 and is formed to cover the insulating layer 5 and the metal wiring 9. In one example, a SiN film is formed as the insulating layer to cover the insulating layer 5 and the metal wiring 9. The spacer layer 6 is formed to cover the insulating layer. That is, in this example, the spacer layer 6 covers the insulating layer 5 and the metal wiring 9 via the insulating layer.

In one example, the photodetection element 1A in which the layered structure 200A includes the insulating layer may be manufactured as follows. First, the semiconductor substrate 3, the semiconductor layer 800, the insulating layer 12, the insulating layer 21, and the substrate 2 illustrated in FIG. 17 are manufactured through the same processes as in the second embodiment described above. Next, the semiconductor layer 800 is removed, and the insulating layer 5 is exposed. Next, the opening 5c for disposing the metal wiring 9 is formed in the insulating layer 5. The formation of the opening 5c is performed, for example, in the same manner as in the second embodiment described above. Next, the metal wiring 9 is formed such that the contact portion 92 is located in the opening 5c. Next, after the insulating layer is formed to cover the insulating layer 5 and the metal wiring 9, the spacer layer 6 is formed to cover the insulating layer. Next, the plurality of lenses 7 are provided on the surface 3a in the same manner as in the second embodiment described above.

In another example, even in a configuration in which the layered structure 200A does not include the semiconductor layer 8, the texture structure may be formed in the photodetection element 1A. In this example, the texture structure may be formed on the insulating layer 5. The texture structure is formed on a surface of the insulating layer 5 located on a side opposite to the semiconductor layer 33. In this example, the spacer layer 6 is formed to cover the texture structure formed on the insulating layer 5. The spacer layer 6 fills concave portions of the texture structure formed on the insulating layer 5.

The photodetection element 1B in which the texture structure is formed on the insulating layer 5 may be manufactured, for example, as follows. First, the semiconductor substrate 3, the insulating layer 5, the semiconductor layer 800, the insulating layer 12, the insulating layer 21, and the substrate 2 illustrated in FIG. 17 are manufactured. Next, the semiconductor layer 800 is removed, and the texture structure is formed on the surface of the insulating layer 5. Next, the opening 5c for disposing the metal wiring 9 is formed in the insulating layer 5 on which the texture structure is formed. The formation of the opening 5c is performed, for example, in the same manner as in the second embodiment described above. Next, the metal wiring 9 is formed such that the contact portion 92 is located in the opening 5c. Next, after the spacer layer 6 is formed to cover the insulating layer 5 on which the texture structure is formed and the metal wiring 9, the plurality of lenses 7 are provided on the surface 3a in the same manner as in the second embodiment described above. Alternatively, the order in which the formation of the texture structure is performed and the order in which the formation of the metal wiring 9 is performed may be reversed. That is, after the semiconductor layer 800 is removed, the opening 5c may be formed first, and the metal wiring 9 may be formed in the formed opening 5c. After the metal wiring 9 is formed, the texture structure may be formed on the surface of the insulating layer 5.

In the photodetection element 1B according to the third embodiment described above, the trench 40 may not penetrate the semiconductor substrate 3. In one example, the trench 40 may reach the epitaxial semiconductor layer 31 and may not open at the surface 3b. That is, in this example, a bottom of the trench 40 may be located inside the epitaxial semiconductor layer 31. The photodetection element 1B in which the bottom of the trench 40 is located inside the epitaxial semiconductor layer 31 tends to more reliably increase the aperture ratio in the avalanche photodiode APD. Therefore, the photodetection element 1B in which the bottom of the trench 40 is located inside the epitaxial semiconductor layer 31 can more reliably improve the detection efficiency.

In one example, the photodetection element 1B in which the bottom of the trench 40 is located inside the epitaxial semiconductor layer 31 may be manufactured as follows. First, the semiconductor substrate 3, the insulating layer 5, the insulating layer 21, and the substrate 2 illustrated in FIG. 25 are manufactured through the same processes as in the third embodiment described above. Next, the trench 40 is provided to reach the epitaxial semiconductor layer 31 from the surface 3a in a direction from the surface 3a toward the surface 3b. As a result, the trench 40 whose bottom is located inside the epitaxial semiconductor layer 31 is provided.

A photodetection element according to one aspect of the present disclosure is [1] “a photodetection element including: a semiconductor substrate including a first surface to be a light-incident surface and a second surface located on a side opposite to the first surface; and a plurality of lenses provided on the first surface, wherein the semiconductor substrate includes: a first epitaxial semiconductor layer including the second surface; and a second epitaxial semiconductor layer located on a side opposite to the second surface with respect to the first epitaxial semiconductor layer, wherein the first epitaxial semiconductor layer includes: an epitaxial semiconductor region of a first conductivity type; and a plurality of semiconductor regions of a second conductivity type, each of which includes the second surface and constitutes an avalanche photodiode together with the epitaxial semiconductor region, wherein the second epitaxial semiconductor layer is adjacent to the epitaxial semiconductor region between the first surface and the epitaxial semiconductor region, wherein each of the plurality of lenses is disposed on the first surface to overlap a corresponding semiconductor region among the plurality of semiconductor regions when viewed from a thickness direction of the semiconductor substrate, wherein the semiconductor substrate is provided with a trench that surrounds each of the semiconductor regions when viewed from the thickness direction and extends in the thickness direction, wherein the epitaxial semiconductor region has an impurity concentration higher than an impurity concentration of the second epitaxial semiconductor layer, wherein the second epitaxial semiconductor layer has a thickness greater than a thickness of the first epitaxial semiconductor layer, and wherein a sum of the thickness of the first epitaxial semiconductor layer and the thickness of the second epitaxial semiconductor layer is 20 μm or more and 50 μm or less.”

In the photodetection element described in [1] above, the second epitaxial semiconductor layer has the thickness greater than the thickness of the first epitaxial semiconductor layer, and the sum of the thickness of the first epitaxial semiconductor layer and the thickness of the second epitaxial semiconductor layer is 20 μm or more and 50 μm or less. In the configuration in which the relationship between the thickness of the first epitaxial semiconductor layer and the thickness of the second epitaxial semiconductor layer satisfies the above-described relationship, a length of the optical path in the photodetection element can be increased compared to a configuration in which a semiconductor substrate includes a single epitaxial semiconductor layer. Here, the detection efficiency is affected not only by the quantum efficiency but also by the avalanche probability, which indicates the probability that generated carriers cause avalanche multiplication. The avalanche probability is affected by the intensity of an electric field generated in the epitaxial semiconductor region when a voltage is applied to the photodetection element. For example, as the intensity of the electric field increases, avalanche multiplication tends to occur, so the avalanche probability increases. In the photodetection element described in [1] above, the epitaxial semiconductor region has the impurity concentration higher than the impurity concentration of the second epitaxial semiconductor layer. Therefore, in the photodetection element described in [1] above, when the voltage is applied, the intensity of the electric field generated in the epitaxial semiconductor region increases.

Furthermore, in the configuration in which the relationship between the thickness of the first epitaxial semiconductor layer and the thickness of the second epitaxial semiconductor layer satisfies the above-described relationship, secondary photons of carriers multiplied in a certain avalanche photodiode tend not to enter an adjacent avalanche photodiode. In addition, in the photodetection element described in [1] above, since the semiconductor substrate is provided with the trench that surrounds each of the semiconductor regions when viewed from the thickness direction, the secondary photons are controlled from entering the adjacent avalanche photodiode.

From the above, the photodetection element described in [1] above improves the detection efficiency and controls crosstalk.

The photodetection element according to one aspect of the present disclosure may be [2] “the photodetection element according to [1], wherein the trench opens at the second surface and reaches at least the second epitaxial semiconductor layer.”

In the photodetection element described in [2] above, the trench reaches at least the second epitaxial semiconductor layer. Therefore, in the photodetection element described in [2] above, the secondary photons of carriers multiplied in a certain avalanche photodiode are further controlled from entering the adjacent avalanche photodiode. That is, the photodetection element described in [2] above further controls crosstalk.

The photodetection element according to one aspect of the present disclosure may be [3] “the photodetection element according to [2], wherein the semiconductor substrate further includes a semiconductor layer of the first conductivity type adjacent to the second epitaxial semiconductor layer between the first surface and the second epitaxial semiconductor layer, wherein the semiconductor layer has an impurity concentration higher than the impurity concentration of the second epitaxial semiconductor layer, and wherein the trench does not reach the semiconductor layer.”

In the photodetection element described in [3] above, the trench does not reach the semiconductor layer adjacent to the second epitaxial semiconductor layer between the second epitaxial semiconductor layer and the first surface. Therefore, the photodetection element described in [3] above can simplify the configuration of the photodetection element.

The photodetection element according to one aspect of the present disclosure may be [4] “the photodetection element according to [1], wherein the trench opens at the first surface and reaches at least the first epitaxial semiconductor layer.”

In the photodetection element described in [4] above, the trench reaches at least the first epitaxial semiconductor layer. The configuration in which the trench reaches at least the first epitaxial semiconductor layer tends to increase the aperture ratio in the avalanche photodiode. Here, the detection efficiency is affected not only by the quantum efficiency and the avalanche probability but also by an aperture ratio in the avalanche photodiode. For example, when the aperture ratio in the avalanche photodiode increases, the detection efficiency increases. Therefore, the photodetection element described in [4] above can further improve the detection efficiency.

The photodetection element according to one aspect of the present disclosure may be [5] “the photodetection element according to any one of [1] to [4], further including a spacer layer provided between the plurality of lenses and the first surface, wherein the sum of the thickness of the first epitaxial semiconductor layer and the thickness of the second epitaxial semiconductor layer is twice or more a sum of a thickness of each of the lens and a thickness of the spacer layer.”

In the photodetection element described in [5] above, the sum of the thickness of the first epitaxial semiconductor layer and the thickness of the second epitaxial semiconductor layer is twice or more the sum of the thickness of each of the lens and the thickness of the spacer layer. In the configuration in which the relationship between the thickness of the first epitaxial semiconductor layer and the thickness of the second epitaxial semiconductor layer satisfies the above-described relationship, the length of the optical path in the photodetection element can be further increased compared to the configuration in which the semiconductor substrate includes a single epitaxial semiconductor layer. Therefore, the photodetection element described in [5] above further improves the detection efficiency and further controls crosstalk.

The photodetection element according to one aspect of the present disclosure may be [6] “the photodetection element according to any one of [1] to [5], further including a plurality of light-reflecting layers provided on the second surface, wherein each of the plurality of light-reflecting layers is disposed on the second surface to oppose a corresponding semiconductor region among the plurality of semiconductor regions and reflects light incident from the first surface.”

In the photodetection element described in [6] above, each of the plurality of light-reflecting layers that reflect light incident from the first surface is disposed on the second surface to oppose the corresponding semiconductor region. The configuration in which the photodetection element includes the plurality of light-reflecting layers described above can further increase the length of the optical path in the photodetection element. Therefore, the photodetection element described in [6] above further improves the detection efficiency and further controls crosstalk.

A method for manufacturing a photodetection element according to one aspect of the present disclosure is [7] “a method for manufacturing a photodetection element, including: preparing a semiconductor substrate including a first surface to be a light-incident surface and a second surface located on a side opposite to the first surface, the semiconductor substrate including a first epitaxial semiconductor layer including the second surface and a second epitaxial semiconductor layer located on a side opposite to the second surface with respect to the first epitaxial semiconductor layer; forming a plurality of semiconductor regions of a second conductivity type by implanting impurities of a conductivity type different from a conductivity type of the first epitaxial semiconductor layer into the first epitaxial semiconductor layer from the second surface side, each of the plurality of semiconductor regions of the second conductivity type including the second surface and constituting an avalanche photodiode together with an epitaxial semiconductor region of a first conductivity type in the first epitaxial semiconductor layer; after the forming, providing a trench that surrounds each of the semiconductor regions when viewed from a thickness direction of the semiconductor substrate and extends in the thickness direction; and providing a plurality of lenses on the first surface to overlap a corresponding semiconductor region among the plurality of semiconductor regions when viewed from the thickness direction, wherein the preparing includes forming the first epitaxial semiconductor layer by epitaxial growth to have an impurity concentration higher than an impurity concentration of the second epitaxial semiconductor layer, and forming the second epitaxial semiconductor layer adjacent to the first epitaxial semiconductor layer between the first surface and the first epitaxial semiconductor layer by epitaxial growth to have a thickness greater than a thickness of the first epitaxial semiconductor layer, and wherein, in the preparing, the first epitaxial semiconductor layer is formed and the second epitaxial semiconductor layer is formed such that a sum of the thickness of the first epitaxial semiconductor layer and the thickness of the second epitaxial semiconductor layer is 20 μm or more and 50 μm or less.”

In the manufacturing method described in [7] above, the first epitaxial semiconductor layer and the second epitaxial semiconductor layer are formed such that the second epitaxial semiconductor layer has the thickness greater than the thickness of the first epitaxial semiconductor layer, and the sum of the thickness of the first epitaxial semiconductor layer and the thickness of the second epitaxial semiconductor layer is 20 μm or more and 50 μm or less. Therefore, in the photodetection element manufactured by the manufacturing method described in [7] above, the length of the optical path in the photodetection element can be increased compared to the configuration in which the semiconductor substrate includes the single epitaxial semiconductor layer. In the manufacturing method described in [7] above, the first epitaxial semiconductor layer is formed to have the impurity concentration higher than the impurity concentration of the second epitaxial semiconductor layer. That is, the epitaxial semiconductor region in the first epitaxial semiconductor layer has the impurity concentration higher than the impurity concentration of the second epitaxial semiconductor layer. Therefore, in the photodetection element manufactured by the manufacturing method described in [7] above, when the voltage is applied, the intensity of the electric field generated in the epitaxial semiconductor region increases.

Furthermore, when the first epitaxial semiconductor layer and the second epitaxial semiconductor layer are formed such that the relationship between the thickness of the first epitaxial semiconductor layer and the thickness of the second epitaxial semiconductor layer satisfies the above-described relationship, secondary photons of carriers multiplied in a certain avalanche photodiode tend not to enter an adjacent avalanche photodiode. In addition, in the manufacturing method described in [7] above, since the trench that surrounds each of the semiconductor regions when viewed from the thickness direction of the semiconductor substrate is provided in the semiconductor substrate, in the photodetection element manufactured by the manufacturing method, the secondary photons are controlled from entering the adjacent avalanche photodiode.

From the above, the photodetection element manufactured by the manufacturing method described in [7] above improves the detection efficiency and controls crosstalk.

According to an aspect of the present disclosure, a photodetection element that improves detection efficiency and controls crosstalk, and a method for manufacturing such a photodetection element are provided.

What is claimed is:

1. A photodetection element comprising:
a semiconductor substrate including a first surface to be a light-incident surface and a second surface located on a side opposite to the first surface; and
a plurality of lenses provided on the first surface,
wherein the semiconductor substrate includes:
a first epitaxial semiconductor layer including the second surface; and
a second epitaxial semiconductor layer located on a side opposite to the second surface with respect to the first epitaxial semiconductor layer,
wherein the first epitaxial semiconductor layer includes:
an epitaxial semiconductor region of a first conductivity type; and
a plurality of semiconductor regions of a second conductivity type, each of which includes the second surface and constitutes an avalanche photodiode together with the epitaxial semiconductor region,
wherein the second epitaxial semiconductor layer is adjacent to the epitaxial semiconductor region between the first surface and the epitaxial semiconductor region,
wherein each of the plurality of lenses is disposed on the first surface to overlap a corresponding semiconductor region among the plurality of semiconductor regions when viewed from a thickness direction of the semiconductor substrate,
wherein the semiconductor substrate is provided with a trench that surrounds each of the semiconductor regions when viewed from the thickness direction and extends in the thickness direction,
wherein the epitaxial semiconductor region has an impurity concentration higher than an impurity concentration of the second epitaxial semiconductor layer,
wherein the second epitaxial semiconductor layer has a thickness greater than a thickness of the first epitaxial semiconductor layer, and
wherein a sum of the thickness of the first epitaxial semiconductor layer and the thickness of the second epitaxial semiconductor layer is 20 μm or more and 50 μm or less.

2. The photodetection element according to claim 1, wherein the trench opens at the second surface and reaches at least the second epitaxial semiconductor layer.

3. The photodetection element according to claim 2, wherein the semiconductor substrate further includes a semiconductor layer of the first conductivity type adjacent to the second epitaxial semiconductor layer between the first surface and the second epitaxial semiconductor layer,
wherein the semiconductor layer has an impurity concentration higher than the impurity concentration of the second epitaxial semiconductor layer, and
wherein the trench does not reach the semiconductor layer.

4. The photodetection element according to claim 1, wherein the trench opens at the first surface and reaches at least the first epitaxial semiconductor layer.

5. The photodetection element according to claim 1, further comprising a spacer layer provided between the plurality of lenses and the first surface,
wherein the sum of the thickness of the first epitaxial semiconductor layer and the thickness of the second epitaxial semiconductor layer is twice or more a sum of a thickness of each of the lens and a thickness of the spacer layer.

6. The photodetection element according to claim 1, further comprising a plurality of light-reflecting layers provided on the second surface,
wherein each of the plurality of light-reflecting layers is disposed on the second surface to oppose a corresponding semiconductor region among the plurality of semiconductor regions and reflects light incident from the first surface.

7. A method for manufacturing a photodetection element, comprising:
preparing a semiconductor substrate including a first surface to be a light-incident surface and a second surface located on a side opposite to the first surface, the semiconductor substrate including a first epitaxial semiconductor layer including the second surface and a second epitaxial semiconductor layer located on a side opposite to the second surface with respect to the first epitaxial semiconductor layer;
forming a plurality of semiconductor regions of a second conductivity type by implanting impurities of a conductivity type different from a conductivity type of the first epitaxial semiconductor layer into the first epitaxial semiconductor layer from the second surface side, each of the plurality of semiconductor regions of the second conductivity type including the second surface and constituting an avalanche photodiode together with an epitaxial semiconductor region of a first conductivity type in the first epitaxial semiconductor layer;
after the forming, providing a trench that surrounds each of the semiconductor regions when viewed from a thickness direction of the semiconductor substrate and extends in the thickness direction; and
providing a plurality of lenses on the first surface to overlap a corresponding semiconductor region among the plurality of semiconductor regions when viewed from the thickness direction,
wherein the preparing includes:
forming the first epitaxial semiconductor layer by epitaxial growth to have an impurity concentration higher than an impurity concentration of the second epitaxial semiconductor layer; and
forming the second epitaxial semiconductor layer adjacent to the first epitaxial semiconductor layer between the first surface and the first epitaxial semiconductor layer by epitaxial growth to have a thickness greater than a thickness of the first epitaxial semiconductor layer, and
wherein, in the preparing, the first epitaxial semiconductor layer is formed and the second epitaxial semiconductor layer is formed such that a sum of the thickness of the first epitaxial semiconductor layer and the thickness of the second epitaxial semiconductor layer is 20 μm or more and 50 μm or less.
